(19) United States
(12) Patent Application Publication
(10) Pub. No.: US 2014/0038389 A1
(43) Pub. Date: Feb. 6, 2014

(54) PROCESSING METHOD OF SEMICONDUCTOR SUBSTRATE AND PROCESSED SEMICONDUCTOR SUBSTRATE PRODUCT

(71) Applicant: Sony Corporation, Tokyo (JP)

(72) Inventor: Hirotaka Kobayashi, Kanagawa (JP)

(73) Assignee: Sony Corporation, Tokyo (JP)

(21) Appl. No.: 13/946,720

(22) Filed: Jul. 19, 2013

(30) Foreign Application Priority Data
Jul. 31, 2012 (JP) 2012-169604

(51) Int. Cl. H01L 21/78

(52) U.S. Cl. CPC H01L 21/78
USPC 438/460

(57) ABSTRACT

Provided is a processing method of a semiconductor substrate, including curing an adhesive layer by radiating UV rays at least on portions of a protective film that come into contact with semiconductor device main body parts before the protective film on which a UV curable adhesive layer is formed is attached to the semiconductor substrate having a first face on which a plurality of semiconductor devices, each of which includes the semiconductor device main body part and connection terminal parts, are formed in a state in which the semiconductor devices are separate from each other, and then attaching non-cured portions of the adhesive layer of the protective film to the outer peripheral portion of the semiconductor substrate, and a region of the semiconductor substrate positioned between the semiconductor devices, and bringing cured portions of the adhesive layer of the protective film into contact with the semiconductor device main body parts.

### BACKGROUND

The present disclosure relates to a processing method of a semiconductor substrate, and a processed semiconductor substrate product, and more particularly to a processing method of a semiconductor substrate and a processed semiconductor substrate product of which a first face of the semiconductor substrate is formed with a semiconductor device.

In general, a plurality of semiconductor devices (for example, solid-state imaging devices) are formed on a first face of a semiconductor substrate using semiconductor processing. Then, in that state, evaluation tests are performed with regard to characteristics and defects or non-defects of the semiconductor devices so as to determine whether the devices are favorable products or defective products. Depending on a request of a client, the device products are shipped to the client in this state. Further, after the products are shipped to the client, following processing steps are performed by, for example, the client or in another factory. The same situation appears in the following description. Next, an adhesive layer of a back grinding tape formed by laminating an adhesive layer and a base material is attached to the first face of the semiconductor substrate on which the semiconductor devices are formed, and then a second face of the semiconductor substrate opposite to the first face is ground so that the semiconductor substrate has a predetermined thickness. Such semiconductor substrates are shipped to a client in this state when requested by the client. Then, the entire second face of the semiconductor substrate is attached to the center part of a dicing sheet, a wafer ring is attached to an outer circumferential portion of the dicing sheet, and then the back grinding tape is peeled. In this case, if the adhesive layer of the back grinding tape is made of a UV curable resin, the adhesive layer is cured by radiating UV rays thereon to reduce adhesiveness, and then the back grinding tape is peeled off.

After that, the semiconductor substrate attached to the dicing sheet is transported to a dicing device using the wafer ring as a support. Then, the semiconductor substrate is cut along a dicing line using a rotating blade to which diamond microparticles are fixed using a binder. In this manner, the semiconductor devices are individualized while the dicing sheet is attached thereto. The devices are shipped to the client in that state when requested by the client.

Depending on cases, dicing may be performed on the semiconductor substrate with the back grinding tape attached without radiating UV rays on the back grinding tape, and then UV rays may be radiated thereon so that the back grinding tape is peeled.

Next, the semiconductor substrate that has been diced with the wafer ring attached is carried onto a chip mounting device, and in a state of the dicing sheet with reduced adhesion strength due to the radiation of UV rays, the dicing sheet is pushed up using a needle-like push-up pin from the back side while being pulled, and thereby the sheet is partially peeled. Then, the semiconductor devices that have been individualized (divided into pieces) are attracted and held by collets. In this manner, the semiconductor devices are picked up from the dicing sheet and transferred onto a support sheet to which another wafer ring is attached. The semiconductor devices are shipped to a client in this state, which is the standard shipping form, when requested by the client. For shipping, the semiconductor devices are stored in a packing case, or the like, in order to minimize adhesion of contaminants, or the like.

After that, the following operations are generally performed in another factory or at a client's discretion. In other words, the semiconductor devices are carried into a chip mounting device while the wafer ring is fixed thereto, and in a state of the support sheet with reduced adhesion strength due to the radiation of UV rays, the support sheet is pulled and pushed up using a needle-like push-up pin from the back side, and then partially peeled. Then, the individualized semiconductor devices are attracted and held by collets. In this manner, the semiconductor devices are picked up from the support sheet, and placed on an adhesive applied onto a transfer part of a package or a printed wiring board. Then, the adhesive is cured through heating, or the like so as to fix the semiconductor devices onto the package or the printed wiring board. Next, connection terminal parts of the semiconductor devices and terminal parts provided on the package or the printed wiring board are electrically connected through wire bonding, or the like. It should be noted that this connection can be set as a flip-chip connection. Finally, a seal resin is applied to an opening part of the package, glass or a lens is placed thereon, the seal resin is cured, and the semiconductor devices can thereby be completed.

In the manufacturing process of semiconductor devices in the related art described above, when a back grinding tape is peeled, there are cases in which the adhesive layer remains on the semiconductor devices. In other words, there are cases in which a so-called “residual adhesive” occurs. When such residual adhesive occurs in a semiconductor device that is constituted by a solid-state imaging element, there is a problem in that spotty image defects are generated on images. In addition, as the size of a semiconductor device is reduced and constituent parts of a semiconductor device are miniaturized, it is difficult to remove an adhesive layer from a semiconductor device when the adhesive layer invades into the semiconductor device, and when a back grinding tape is attached to a semiconductor device, there is also a problem in that air bubbles are formed between the semiconductor device and the adhesive layer thereof, which results in an uneven curing state of the adhesive layer by UV rays.

In addition, there is also another problem in that, when a semiconductor device is uncovered during a manufacturing process, a transporting process, and the like thereof, contaminants, or the like adhere to the semiconductor device.

### SUMMARY

Japanese Unexamined Patent Application Publication No. H5-062950 discloses a method for attaching a protection tape to a semiconductor wafer in which a protection tape that can control adhesion strength thereof is used to be attached only to peripheral portions of the semiconductor wafer in an intense adhesion state. Since the protection tape is attached only to the peripheral portions of the semiconductor wafer in the intense adhesion state, there is no problem of such a residual adhesive as described above. However, since the protection tape is not attached to the peripheral portions of individual semiconductor devices, problems easily arise when a second face of the semiconductor substrate is ground. In other words, there is concern of the protection tape deviating from the center of the semiconductor wafer, and scratches or dents being made on a surface of the semiconductor wafer. In addition, crinkles are made in the protection tape, and in a worst case, the semiconductor wafer is damaged.

In addition, Japanese Unexamined Patent Application Publication No. 2001-102330 discloses a manufacturing method of a substrate in which, when a plurality of substrates are cut out from a mother board so as to obtain the plurality of substrates from the mother board, a water-soluble first protective film is formed on the surface of the mother board, then a water-insoluble second protective film is formed on the water-soluble first protective film, the plurality of substrates are cut out by cutting the mother board on which the first and the second protective films are formed, the cut substrates are cleaned with a solvent so as to remove the second protective film, and then the first protective film is removed by being cleaned with water. This technology can prevent adhesion of contaminants, or the like on the substrates when the substrates are cut out. However, when this technology is applied to the manufacturing method of a semiconductor device described above, connection terminal parts of a semiconductor device are covered by the first protective film and the second protective film, and thus there is a problem in that it is difficult to evaluate or test the characteristics and defects or non-defects of the semiconductor device.

Therefore, it is desirable to provide a processing method of a semiconductor substrate and a processed semiconductor substrate product that enable prevention of problems of residual adhesives and adhesion of contaminants to a semiconductor device during a manufacturing process and a transporting process of the semiconductor device. In addition, it is further desirable to provide a processing method of a semiconductor substrate and a processed semiconductor substrate product which enable easy evaluation and tests of characteristics, and defects or non-defects of a semiconductor device.

According to a first embodiment of the present disclosure, there is provided a processing method of a semiconductor substrate, the method including (A) curing an adhesive layer by radiating UV rays at least on portions of a protective film that come into contact with semiconductor device main body parts before the protective film on which a UV curable adhesive layer is formed is attached to the semiconductor substrate having a first face on which a plurality of semiconductor devices, each of which includes a semiconductor device main body part and connection terminal parts, are formed in a state in which the semiconductor devices are separate from each other, and then (B) attaching non-cured portions of the adhesive layer of the protective film to an outer peripheral portion of the semiconductor substrate, and a region of the semiconductor substrate positioned between the semiconductor devices, and bringing cured portions of the adhesive layer of the protective film into contact with the semiconductor device main body parts.

According to a second embodiment of the present disclosure, there is provided a processing method of a semiconductor substrate, the method including (A) forming a plurality of semiconductor devices, each of which includes a semiconductor device main body part and connection terminal parts, on a first face of the semiconductor substrate in a state in which the semiconductor devices are separate from each other, and then (B) forming a water-soluble protective film on semiconductor device main body parts except for a region of the first face of the semiconductor substrate on which the semiconductor devices are not formed, and the connection terminal parts.

According to a third embodiment of the present disclosure, there is provided a processing method of a semiconductor substrate, the method including (A) forming a plurality of semiconductor devices, each of which includes a semiconductor device main body part and connection terminal parts, on a first face of a semiconductor substrate in the state in which the semiconductor devices are separated from each other, then (B) attaching a polishing protective sheet onto the semiconductor devices and the first face of the semiconductor substrate, polishing a second face of the semiconductor substrate opposite to the first face, attaching a dicing sheet to the second face of the semiconductor substrate, and removing the polishing protective sheet, and then (C) forming a water-soluble protective film on semiconductor device main body parts except for a region of the first face of the semiconductor substrate on which the semiconductor devices are not formed, and the connection terminal parts.

According to the first embodiment of the present disclosure, there is provided a processed semiconductor substrate product including (a) a semiconductor substrate having a first face on which a plurality of semiconductor devices, each of which includes a semiconductor device main body part and connection terminal parts, are formed in a state in which the semiconductor devices are separate from each other, and (b) a protective film that is formed with a UV curable adhesive layer and that covers the first face of the semiconductor substrate. An adhesive layer is cured on portions of the protective film that come into contact with the semiconductor device main body parts. And an adhesive layer of the protective film attached to an outer peripheral portion of the semiconductor substrate, and a region of the semiconductor substrate positioned between the semiconductor devices is not cured.

According to the second embodiment of the present disclosure, there is provided a processed semiconductor substrate product including (a) a semiconductor substrate having a first face on which a plurality of semiconductor devices, each of which includes a semiconductor device main body part and connection terminal parts, are formed in a state in which the semiconductor devices are separate from each other, and (b) a water-soluble protective film that is formed on semiconductor device main body parts except for a region of the first face of the semiconductor substrate on which the semiconductor devices are not formed, and the connection terminal parts.

In the processing method of a semiconductor substrate according to the first embodiment of the present disclosure or the processed semiconductor substrate product according to the first embodiment of the present disclosure, portions of the adhesive layer of the protective film that come into contact with a semiconductor device main body part of each semiconductor device that is vulnerable to adhesion of contaminants or the like are cured, and portions of the adhesive layer of the protective film attached to the outer peripheral portion of the semiconductor substrate and regions of the semiconductor substrate positioned between the semiconductor devices are not cured. For this reason, the occurrence of problems of a residual adhesive arising from the adhesive layer remaining on the semiconductor device main body part, and of a difficulty in removing the adhesive layer from the semiconductor device main body part resulting from intrusion of the adhesive layer to the semiconductor device main body part and then curing of the adhesive layer due to radiation of UV rays can be reliably avoided. Moreover, since the protective film is attached to the vicinity of individual semiconductor device main body parts, when the second face of the semiconductor substrate is polished, problems of intrusion of contaminants to the semiconductor device main body parts, and scratches made on the semiconductor device main body parts that result from friction between the semiconductor device main body parts and the cured adhesive layer of the protective film seldom occur. Furthermore, when the semiconductor substrate is diced while being attached with the protective film, adhesion of dust generated from dicing can be prevented. In addition, contaminants do not adhere to the semiconductor device main body parts even during transportation, or when they are stored in an environment in which contaminants easily adhere, regardless of execution of dicing. Thus, the semiconductor substrate can be stored in such an environment in which contaminants easily adhere. In addition, not only because the adhesion of contaminants to the semiconductor device main body parts can be prevented, but also because the portions of the adhesive layer of the protective film that come into contact with the semiconductor device main body parts are cured, the semiconductor devices are not adversely affected by the attachment of the adhesive layer even when the semiconductor devices are stored for a long period of time. Furthermore, when the semiconductor devices are diced in the state in which the protective film is attached to the semiconductor substrate, the protective film is attached to the outer peripheral portion of the semiconductor substrate and to the regions of the semiconductor substrate positioned between the semiconductor devices, and thus intrusion and adhesion of dicing dust or contaminants can be reliably prevented. In addition, when the water-soluble protective film is formed between the semiconductor device main body parts and the protective film, for example, intrusion of water to the water-soluble protective film can be reliably prevented, and dissolution of the water-soluble protective film can be prevented. Furthermore, when the semiconductor substrate is diced while the protective film is attached thereto, and collets attract and hold the semiconductor devices, occurrence of damage to the semiconductor devices can be reliably prevented.

With regard to the processing method of a semiconductor substrate according to the second and third embodiments of the present disclosure or the processed semiconductor substrate product according to the second embodiment of the present disclosure, the water-soluble protective film is formed on the semiconductor device main body parts except for the regions of the first face of the semiconductor substrate in which the semiconductor devices are not formed and the connection terminal parts of the semiconductor devices, and thus tests for evaluating characteristics and defects or non-defects of the semiconductor devices can be performed while preventing adhesion of contaminants or the like to the semiconductor device main body parts which are regions particularly vulnerable to adhesion of contaminants. In addition, if the second face of the semiconductor substrate is polished after a back grinding tape is attached onto the water-soluble protective film, the back grinding tape is attached via the water-soluble protective film, and thus the problem of a residual adhesive seldom occurs. Moreover, even when the semiconductor devices are stored for a long period of time, the semiconductor devices are not adversely affected by the water-soluble protective film. Furthermore, when the semiconductor substrate is diced with the water-soluble protective film formed thereon, and the semiconductor devices are attracted and held by collets, occurrence of damage to the semiconductor devices can be reliably prevented. Finally, after a process of drawing out terminals from the connection terminal parts of the semiconductor devices is performed, the water-soluble protective film can be easily removed through water-cleaning. Since contaminants adhering on the water-soluble protective film after the application of the water-soluble protective film can also be cleaned out in the foregoing water cleaning, the steps from application to water cleaning of the water-soluble protective film can be executed under an environment in which adhesion of contaminants occurs more easily than usual, and accordingly, efforts necessary for setting, maintaining, and managing a clean environment in which adhesion of contaminants rarely occurs can be drastically reduced, and thereby production can be achieved at lower cost.

### BRIEF DESCRIPTION OF THE DRAWINGS

FIGS. 1A, 1B, 1C, 1D, and 1E are schematic end face views of a semiconductor substrate and the like for describing a processing method of the semiconductor substrate according to Example 1 of the present disclosure;

FIGS. 2A, 2B, and 2C are schematic end face views of the semiconductor substrate and the like for describing the processing method of the semiconductor substrate according to Example 1 of the present disclosure subsequent to FIG. 1E;

FIGS. 3A and 3B are schematic end face views of the semiconductor substrate and the like for describing the processing method of the semiconductor substrate according to Example 1 of the present disclosure subsequent to FIG. 2C;

FIGS. 4A, 4B, 4C, and 4D are schematic end face views of the semiconductor substrate and the like for describing a processing method of a semiconductor substrate according to Example 2 of the present disclosure;

FIGS. 5A, 5B, 5C, and 5D are schematic end face views of the semiconductor substrate and the like for describing a processing method of a semiconductor substrate according to Example 3 of the present disclosure;

FIGS. 6A, 6B, 6C, 6D, and 6E are schematic end face views of the semiconductor substrate and the like for describing a processing method of the semiconductor substrate according to Example 4 of the present disclosure;

FIGS. 7A, 7B, 7C, and 7D are schematic end face views of the semiconductor substrate and the like for describing the processing method of the semiconductor substrate according to Example 4 of the present disclosure subsequent to FIG. 6E;

FIGS. 8A, 8B, 8C, and 8D are schematic end face views of the semiconductor substrate and the like for describing a processing method of the semiconductor substrate according to Example 5 of the present disclosure;

FIGS. 9A, 9B, 9C, and 9D are schematic end face views of the semiconductor substrate and the like for describing the processing method of the semiconductor substrate according to Example 5 of the present disclosure subsequent to FIG. 8D;

FIGS. 10A, 10B, and 10C are schematic end face views of the semiconductor substrate and the like for describing a processing method of the semiconductor substrate according to Example 6 of the present disclosure;

FIGS. 11A, 11B, 11C, 11D, and 11E are schematic end face views of the semiconductor substrate and the like for describing a processing method of the semiconductor substrate according to Example 7 of the present disclosure;

FIGS. 12A and 12B are schematic end face views of the semiconductor substrate and the like for describing the processing method of the semiconductor substrate according to Example 7 of the present disclosure;

FIGS. 13A and 13B are respectively a schematic plan view of one semiconductor device (solid-state imaging element), and a schematic cross-sectional view of two semiconductor devices (solid-state imaging elements);

FIG. 14A is a schematic plan view of a protective film, and FIGS. 14B and 14C are schematic cross-sectional views of the protective film;

FIG. 15 is a schematic plan view of an exposure mask;

FIG. 16 is a schematic diagram showing a state of the protective film attached to a semiconductor substrate;

FIGS. 17A, 17B, 17C, 17D, and 17E are schematic cross-sectional views of a semiconductor substrate and the like for describing steps for picking up a semiconductor device from a dicing sheet to complete the semiconductor device;

FIG. 18 is a schematic cross-sectional view of the semiconductor substrate and the like for describing the steps for picking up the semiconductor device from the dicing sheet to complete the semiconductor device subsequent to FIG. 17E;

FIG. 19 is a flowchart for describing the processing methods of a semiconductor substrate of Examples 1, 2, and 3;

FIG. 20 is a flowchart for describing the processing method of a semiconductor substrate of Example 4;

FIG. 21 is a flowchart for describing the processing method of a semiconductor substrate of Example 5;

FIG. 22 is a flowchart for describing the processing method of a semiconductor substrate of Example 6; and

FIG. 23 is a flowchart for describing the processing method of a semiconductor substrate of Example 7.

### DETAILED DESCRIPTION OF THE EMBODIMENT(S)

Hereinafter, the present disclosure will be described based on Examples with reference to the appended drawings, and the present disclosure is not limited to Examples, and various numerical values and materials in Examples are merely examples. It should be noted that description will be provided in the following order.

1. Overall description of processing methods of a semiconductor substrate according to first to third embodiments of the present disclosure, and of processed semiconductor substrate products according to the first and second embodiments of the present disclosure

2. Example 1 (The processing method of a semiconductor substrate according to the first embodiment of the present disclosure and the processed semiconductor substrate product according to the first embodiment of the present disclosure)

3. Example 2 (Modification of Example 1)

4. Example 3 (Another modification of Example 1)

5. Example 4 (The processing method of a semiconductor substrate according to the second embodiment of the present disclosure and the processed semiconductor substrate product according to the second embodiment of the present disclosure)

6. Example 5 (Modification of Example 4)

7. Example 6 (The processing method of a semiconductor substrate according to the third embodiment of the present disclosure and the processed semiconductor substrate product according to the third embodiment of the present disclosure)

8. Example 7 (Modification of Example 6)

9. Example 8 (Modification of Examples 1 to 7)

10. Example 9 (Modification of Examples 1 to 8)

11. Example 10 (Semiconductor device that is constituted by a solid-state imaging element), and others

[Overall Description of Processing Methods of a Semiconductor Substrate According to First to Third Embodiments of the Present Disclosure, and of Processed Semiconductor Substrate Products According to the First and Second Embodiments of the Present Disclosure]

A processed semiconductor substrate product according to a first embodiment of the present disclosure can have a protective film and a semiconductor substrate in the form in which they have been diced. In addition, a processed semiconductor substrate product according to a second embodiment of the present disclosure can have a water-soluble protective film and a semiconductor substrate in the form in which they have been diced. Alternatively, the processed semiconductor substrate product according to a second embodiment of the present disclosure can be in the form in which a water-insoluble protective film is formed on the water-soluble protective film, a connection terminal part, and a first face of the semiconductor substrate, and in this case, the water-insoluble protective film, the water-soluble protective film, and the semiconductor substrate can be in the diced form. Further, with respect to the processed semiconductor substrate product according to the second embodiment of the present disclosure, including the described preferred forms, and the processed semiconductor substrate product according to the first embodiment of the present disclosure, a second face of the semiconductor substrate opposite to the first face is preferably in the polished form. Further, a dicing sheet can be attached onto the second face of the semiconductor substrate, and the semiconductor substrate can be in the diced form. In addition, the processed semiconductor substrate product according to the second embodiment of the present disclosure including the preferred forms described above can be in the form in which the water-soluble protective film is removed from a defective semiconductor device product.

In the processing method of a semiconductor substrate according to the first embodiment of the present disclosure, a second face of a semiconductor substrate opposite to a first face is preferably polished after a step (B). Then, in this case, after the second face of the semiconductor substrate is polished, a dicing sheet is preferably attached to the second face of the semiconductor substrate.

Furthermore, after the dicing sheet is attached to the second face of the semiconductor substrate, the protective film and the semiconductor substrate are preferably diced, and in this case, after the protective film and the semiconductor substrate are diced, UV rays are preferably radiated on the protective film so as to cure an adhesive layer and then to peel the protective film off.

Furthermore, in this case, after UV rays are radiated on the protective film, it is preferable that a peeling film be attached onto the protective film and then the protective film be peeled off. Alternatively, in this case, after the protective film and the semiconductor substrate are diced, it is preferable that the peeling film be attached onto the protective film before UV rays are radiated onto the protective film, and then UV rays be radiated onto the protective film via the peeling film during radiation of the UV rays onto the protective film.

Alternatively, after the dicing sheet is attached to the second face of the semiconductor substrate, it is preferable that UV rays be radiated onto the protective film, the adhesive layer be cured, the protective film be peeled off, and then the semiconductor substrate be diced.

The processing method of a semiconductor substrate according to the second embodiment of the present disclosure preferably includes a step (C) in which the water-insoluble protective film is formed on the water-soluble protective film, the connection terminal part, and the first face of the semiconductor substrate, subsequent to the step (B). Then, in this case, it is preferable for, after the step (C), the second face of the semiconductor substrate opposite to the first face to be polished, the dicing sheet to be attached onto the second face of the semiconductor substrate and the semiconductor substrate to be diced after the second face of the semiconductor substrate is polished, and further, for the peeling film to be attached onto the water-insoluble protective film, and then the peeling film and the water-insoluble protective film to be removed from the water-soluble protective film after the semiconductor substrate is diced. However, depending on a material included in the water-insoluble protective film, the water-insoluble protective film can be removed from the water-soluble protective film by, for example, dissolving or peeling the water-insoluble protective film using a solvent.

Alternatively, in the processing method of a semiconductor substrate according to the second embodiment of the present disclosure, preferably, the second face of the semiconductor substrate opposite to the first face is polished after a back grinding tape is attached onto the water-soluble protective film, the connection terminal part, and the first face of semiconductor substrate, subsequent to the step (B), and in this case, the dicing sheet is attached onto the second face of the semiconductor substrate and then the back grinding tape is removed after the second face of the semiconductor substrate is polished, the water-insoluble protective film is formed on the water-soluble protective film, the connection terminal part, and the first face of the semiconductor substrate after the back grinding tape is removed, further, the semiconductor substrate is diced after the water-insoluble protective film is formed, and further, the peeling film is attached to the water-insoluble protective film, and then the peeling film and the water-insoluble protective film are removed from the water-soluble protective film after the semiconductor substrate is diced. However, depending on a material included in the water-insoluble protective film, the water-insoluble protective film can be removed from the water-soluble protective film by, for example, dissolving or peeling the water-insoluble protective film using a solvent.

The processing method of a semiconductor substrate according to a third embodiment of the present disclosure preferably includes a step (D) in which a water-insoluble protective film is formed on a water-soluble protective film, a connection terminal part, and a first face of the semiconductor substrate, subsequent to the step (C), and in this case, it is preferable that the semiconductor substrate be diced, subsequent to the step (D), and further, it is preferable that a peeling film be attached onto the water-insoluble protective film and then the peeling film and the water-insoluble protective film be removed from the water-soluble protective film after the semiconductor substrate is diced. However, depending on a material included in the water-insoluble protective film, the water-insoluble protective film can be removed from the water-soluble protective film by, for example, dissolving or peeling the water-insoluble protective film using a solvent.

Alternatively, in the processing method of a semiconductor substrate according to the third embodiment of the present disclosure, it is preferable to dice the semiconductor substrate between the step (B) and the step (C), and in this case, it is preferable to move a non-detective semiconductor device to a support sheet after the semiconductor substrate is diced.

With regard to the processing methods of a semiconductor substrate according to the first to the third embodiments of the present disclosure including the preferred forms and configurations described above, or the processed semiconductor substrate products according to the first and second embodiments of the present disclosure, as a semiconductor device, a sold-state imaging element, an MEMS (Micro Electro Mechanical System), and a digital micromirror device (DMD) can be exemplified. As a semiconductor substrate, not only a silicon semiconductor substrate, but also a Si—Ge substrate, a Ge substrate, a chalcopyrite-based substrate including Cu, In, Ga, Al, Se, S, or the like (for example, a Cu—In—Ga—Se substrate), a GaAs substrate, and the like can be exemplified. In addition, when a semiconductor device is constituted by a solid-state imaging element, a wavelength band of light reception sensitivity of the solid-state imaging element can be extended or altered. A semiconductor device can be manufactured based on a manufacturing method of the related art.

As a configuration and a structure of a protective film, a laminating structure of a base material and a UV curable adhesive layer can be exemplified. The adhesive layer is formed on, for example, a supporting member. In other words, the entire protective film before use has a laminating structure the supporting member, the adhesive layer, and the base material. As a material included in the UV curable adhesive layer, acrylic resins can be exemplified, and a base material included in the protective film, a polyolefin such as low-density polyethylene, linear low-density polyethylene, polypropylene, or polybutene, an ethylene copolymer such as an ethylene-vinyl acetate copolymer, an ethylene-(meth)acrylic acid copolymer, or an ethylene-(meth)acrylic acid ester copolymer, a polyester such as polyethylene terephthalate, or polyethylene naphthalate, polyvinyl chloride, acrylic rubber, polyamide, urethane, or polyimide can be exemplified. For the method for attaching the protective film, and the method for radiating UV rays on the protective film, methods of the related art may be employed, and for the method for peeling the protective film, peeling methods of the related art may be employed. A polishing protective sheet can be configured as, for example, the protective film described above.

As a material included in a water-soluble protective film, a polyvinyl alcohol-based resin, a polyvinyl pyrrolidone-based resin, carboxymethyl cellulose, hydroxyethyl cellulose, or hydroxypropyl cellulose can be exemplified, and as a material included in a water-insoluble protective film, a rubber-based resin, a novolak-based resin, a hydroxylene-based resin, or a polyvalent acrylic resin can be exemplified. The water-soluble protective film and the water-insoluble protective film can be formed based on various printing methods such as a screen printing method, or an ink jet printing method, an offset printing method, a reverse offset printing method, a gravure printing method, a gravure offset printing method, a relief printing method, a flexographic printing method, and a micro-contact method, or various application methods such as a method using a dispenser, or a stamp method. Methods for peeling and removing the water-soluble protective film and the water-insoluble protective film may be appropriately selected according to the materials included in the water-soluble protective film and the water-insoluble protective film, and the water-soluble protective film can be peeled and removed using, for example, water or warm water, and the water-insoluble protective film can be peeled and removed using a solvent.

For the dicing sheet, the back grinding tape, and the peeling film, a dicing sheet, a back grinding tape, and a peeling film having a configuration and a structure of the related art may be used, and for the methods for attaching, peeling, and removing the dicing sheet, the back grinding tape, and the peeling film, attaching, peeling, and removing methods of the related art may be employed. For the method for polishing a second face of a semiconductor substrate, and the method for dicing a semiconductor substrate, or the like, methods of the related art may be employed.

### Example 1

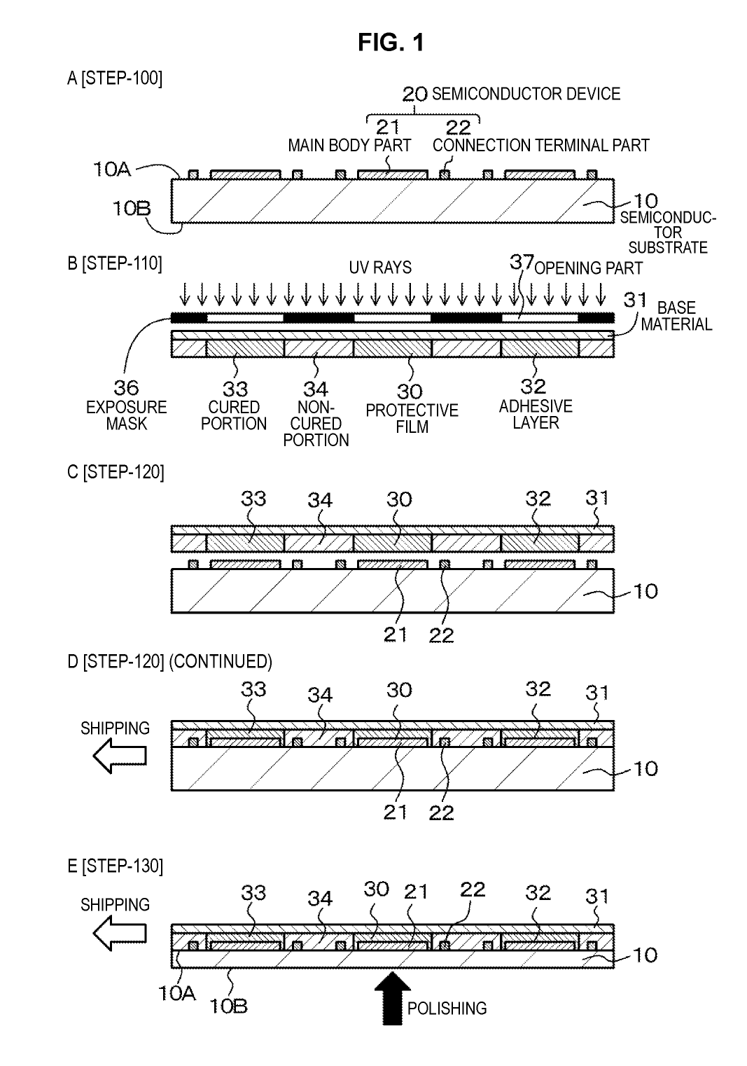

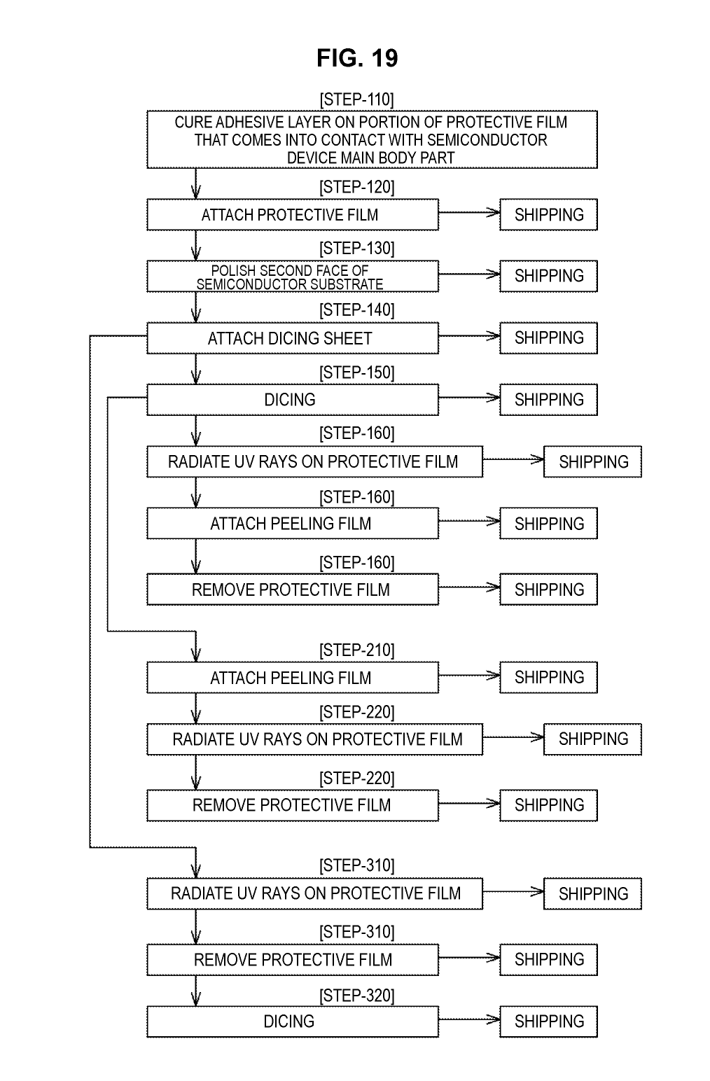

Example 1 relates to the processing method of a semiconductor substrate according to the first embodiment of the present disclosure, and the processed semiconductor substrate product according to the first embodiment of the present disclosure. FIGS. 1A, 1B, 1C, 1D, 1E, 2A, 2B, 2C, 3A, and 3B show schematic end face diagrams of a semiconductor substrate and the like for describing the processing method of a semiconductor substrate of Example 1. Hereinafter, the processing method of a semiconductor substrate and the processed semiconductor substrate product of Example 1 will be described with reference to the drawings, and further to FIG. 19 that is a flowchart for describing the processing method of a semiconductor substrate. It should be noted that, in each Example, a semiconductor device is constituted by a solid-state imaging element, and is formed on a semiconductor substrate configured as a silicon semiconductor substrate.

[Step-100]

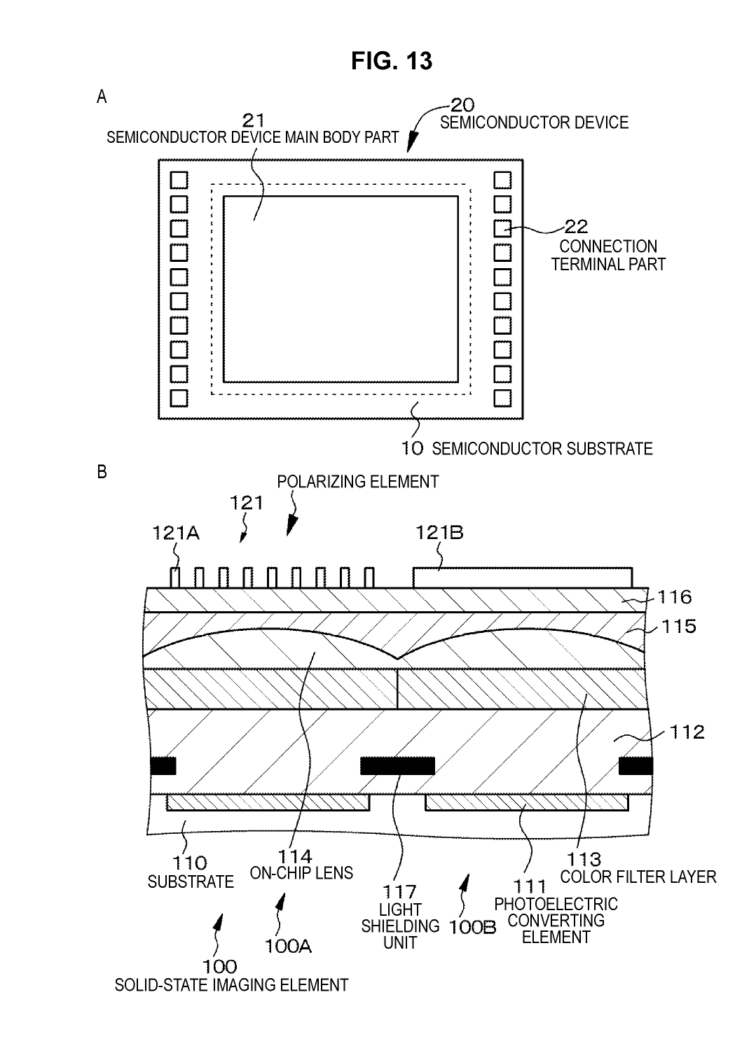

First, a semiconductor device 20 that is constituted by a solid-state imaging element is manufactured on a semiconductor substrate 10 that is configured to be a silicon semiconductor substrate (see FIG. 1A) using a method of the related art. To be specific, a plurality of semiconductor devices 20, each of which includes a semiconductor device main body part 21 (specifically, an imaging unit) and connection terminal parts 22, are formed on a first face 10A of the semiconductor substrate in a state in which the semiconductor devices are separated from each other using a method of the related art. It should be noted that FIG. 13A shows a schematic plan view of one semiconductor device 20. Detailed configuration and structure of the semiconductor device main body part 21 (imaging unit) will be described later.

Then, the semiconductor substrate 10 is carried into a characteristic evaluation device for evaluating the characteristics of the semiconductor devices 20. In addition, predetermined electric characteristic evaluation is conducted on individual semiconductor devices by bringing a measuring probe into contact with the connection terminal parts 22 of the semiconductor devices 20 so as to determine the devices to be defective products or non-defective products. When each of the semiconductor devices is constituted by a solid-state imaging element, evaluation may be performed by radiating light thereon for characteristic evaluation.

[Step-110]

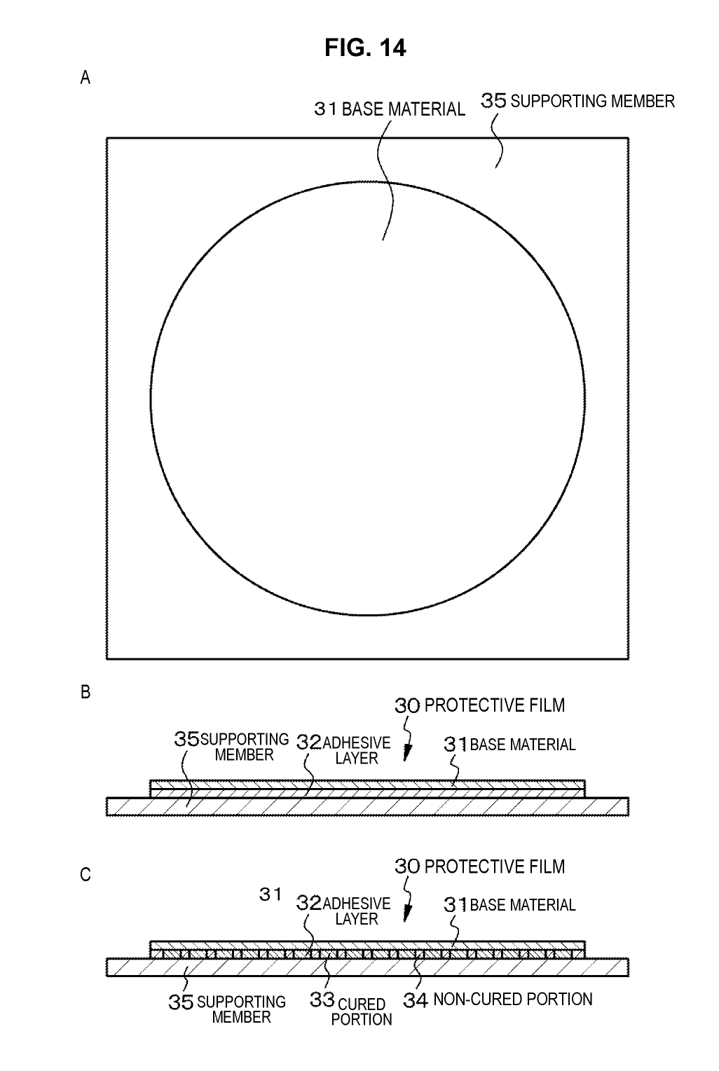

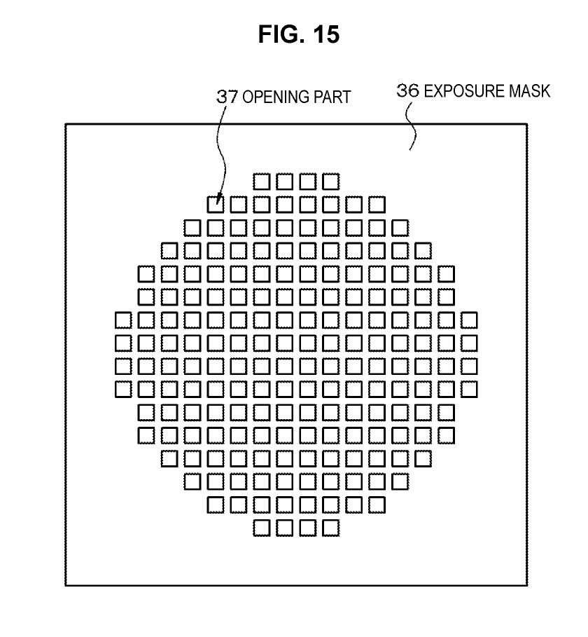

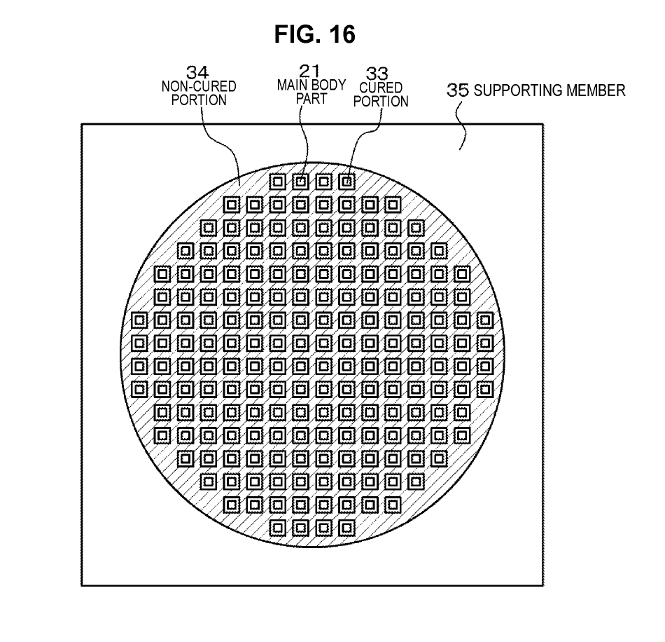

In Example 1, before a protective film 30 on which a UV curable adhesive layer 32 is formed is attached to the semiconductor substrate 10 having the first face 10A on which the plurality of semiconductor devices 20 including the semiconductor device main body part 21 and the connection terminal parts 22 are formed while being separated from each other, UV rays are radiated on portions of the protective film 30 coming into contact at least with the semiconductor device main body part 21 to cure the adhesive layer 32. To be specific, as shown in FIG. 1B, UV rays are radiated onto the protective film 30 to selectively cure the adhesive layer 32 using an exposure mask 36 on which opening parts 37 are provided. The opening parts 37 are provided to correspond to the portions of the protective film 30 coming into contact with the semiconductor device main body parts 21. Reference numeral 33 indicates a cured portion of the adhesive layer 32, and reference numeral 34 indicates a non-cured portion of the adhesive layer 32. In FIG. 13A, the boundary of the cured portion 33 and the non-cured portion 34 of the adhesive layer 32 is indicated by a dashed line. Here, the protective film 30 includes a base material 31 formed of an olefin-based or a polyvinyl chloride-based transparent film, and the adhesive layer 32, which is formed on one face of the base material 31, formed of a UV curable adhesive such as an acrylic resin. It should be noted that, as shown in FIG. 14B or 14C, the adhesive layer 32 is formed on a supporting member 35 formed of, for example, a polyester film. However, the supporting member 35 is omitted in drawings other than FIGS. 14B and 14C. In addition, FIG. 14A shows a schematic plan view of the protective film 30, FIG. 14B shows a schematic cross-sectional view of the protective film 30 before radiation of UV rays, FIG. 14C shows a schematic cross-sectional view of the protective film 30 after radiation of UV rays, and FIG. 15 shows a schematic plane view of the exposure mask 36. In addition, FIG. 16 schematically shows the state of the protective film 30 attached to the semiconductor substrate 10 after radiation of UV rays, the non-cured portions 34 of the adhesive layer are indicated by diagonal lines, and among the portions shown in double squares, the cured portions 33 of the adhesive layer are indicated by the outer square areas, and the semiconductor device main body parts 21 are indicated by the inner square areas.

[Step-120]

Next, the non-cured portions of the adhesive layer 32 of the protective film 30 are attached to the outer peripheral portion of the semiconductor substrate 10 and regions between the semiconductor devices 20, and the cured portions of the adhesive layer 32 of the protective film 30 are brought into contact with the semiconductor device main body parts 21 (see FIGS. 1C and 1D). To be specific, the cured portions of the adhesive layer 32 of the protective film 30 (the cured portions 33) are brought into contact with the semiconductor device main body parts 21 while the supporting member 35 is peeled. On the other hand, the non-cured portions of the adhesive layer 32 of the protective film 30 (the non-cured portions 34) are attached to the outer peripheral portion of the semiconductor substrate 10, the regions between the semiconductor devices 20, and the connection terminal parts 22.

In this manner, a processed semiconductor substrate product can be obtained as shown in FIG. 1D, the product including:

(a) the semiconductor substrate 10 having the first face 10A on which the plurality of semiconductor devices 20, each of which includes the semiconductor device main body part 21 and the connection terminal parts 22, are formed in the state in which the semiconductor devices are separated from each other; and

(b) the protective film 30 which is formed with a UV curable adhesive layer 32 and covers the first face 10A of the semiconductor substrate 10, in which the portions of the adhesive layer 32 of the protective film 30 coming into contact with the semiconductor device main body parts 21 are cured, and the portions of the adhesive layer 32 of the protective film 30 attached to the outer peripheral portion of the semiconductor substrate 10 and the regions of the semiconductor substrate 10 positioned between the semiconductor devices 20 are not cured.

To be more specific, the portions of the adhesive layer 32 on the semiconductor device main body parts 21 and the outer edges thereof, and further portions of the semiconductor substrate 10 adjacent to the semiconductor device main body part 21 are cured. On the other hand, the portions of the adhesive layer 32 on the outer peripheral portion of the semiconductor substrate 10, the regions of the semiconductor substrate 10 positioned between the semiconductor devices 20, and of the protective film 30 attached to the outer peripheral portions of the semiconductor devices 20 (including the connection terminal parts 22) are not cured.

It should be noted that such semiconductor substrates are shipped in the state shown in FIG. 1D when requested by a client. It should also be noted that, when the semiconductor substrates are shipped to the client, following processes are performed on, for example, the client side or in another factory. The same situation applies in description provided below.

[Step-130]

Next, a second face 10B of the semiconductor substrate opposite to the first face 10A is polished (See FIG. 1E) based on a method of the related art. Depending on a request of a client, the semiconductor substrate is shipped in the state shown in FIG. 1E.

[Step-140]

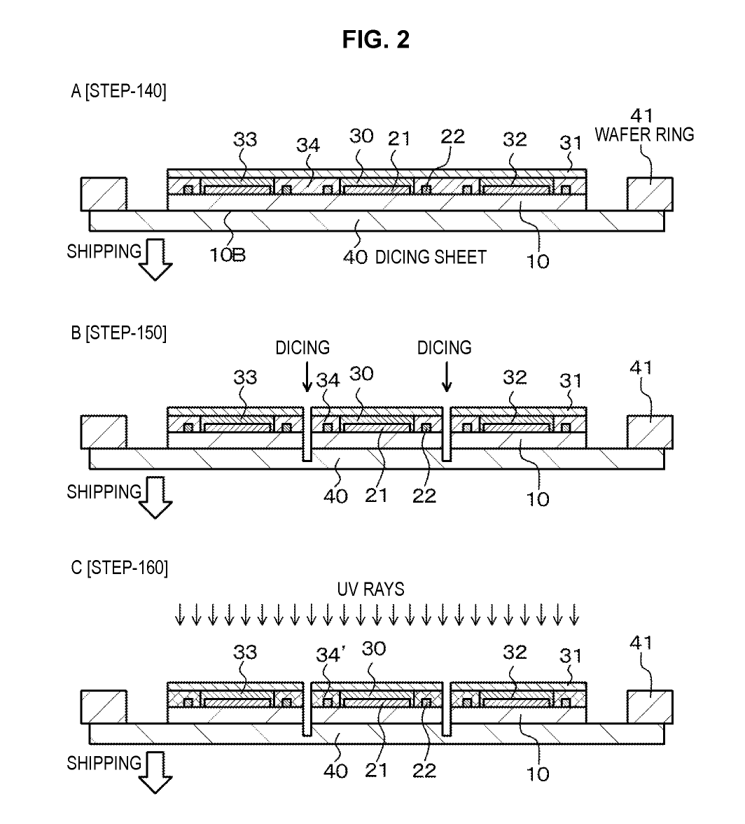

Then, a dicing sheet 40 is attached to the second face 10B of the semiconductor substrate 10 (See FIG. 2A). To be specific, the entire second face 10B of the semiconductor substrate 10 is attached to the center portion of the dicing sheet 40, and then a wafer ring 41 is attached to the outer peripheral portion of the dicing sheet 40. When requested by a client, the semiconductor substrate is shipped in the state shown in FIG. 2A.

[Step-150]

Next, the protective film 30 and the semiconductor substrate 10 are diced using a dicing device of the related art based on a dicing method of the related art (See FIG. 2B). When requested by a client, the semiconductor substrate is shipped in the state shown in FIG. 2B.

[Step-160]

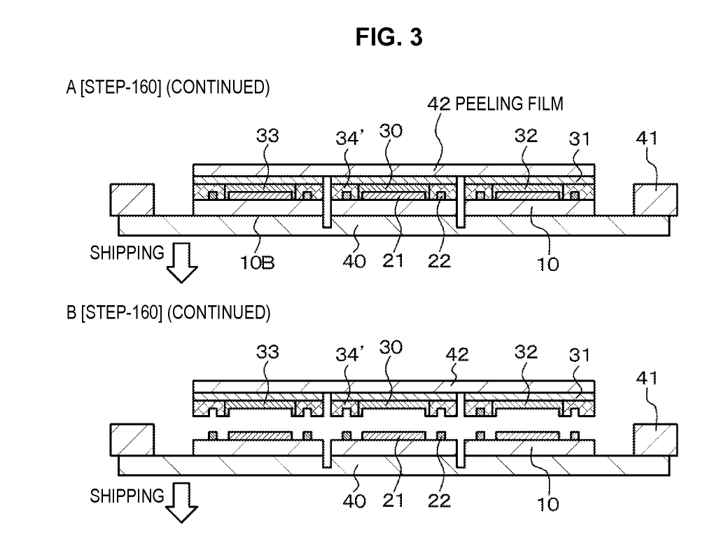

Then, UV rays are radiated on the protective film 30, and then the adhesive layer 32 is cured and the protective film 30 is peeled. To be specific, the non-cured portions 34 of the adhesive layer 32 are cured by radiating UV rays on the protective film 30, and accordingly, adhesiveness of the adhesive layer 32 is reduced (See FIG. 2C). In FIG. 2C, reference numeral 34′ indicates the state in which the non-cured portions 34 are cured. Next, a peeling film 42 which is formed such that the acryl-based or rubber-based adhesive layer 32 is formed beneath the base material 31 made of polyethylene, polyester, polypropylene, or the like is attached to the protective film 30 (See FIG. 3A), and then the protective film 30 is peeled (See FIG. 3B). When requested by a client, the semiconductor substrate is shipped in the state shown in FIG. 2C, 3A, or 3B.

As described above, in Example 1, the portions of the adhesive layer 32 of the protective film 30 coming into contact with the semiconductor device main body parts 21 (cured portions 33) are cured, and the portion of the adhesive layer 32 on the outer peripheral portion of the semiconductor substrate 10, the regions of the semiconductor substrate 10 positioned between the semiconductor devices 20, and further of the protective film 30 attached to the outer peripheral portions of the semiconductor devices 20 (including the connection terminal parts 22) (non-cured portions 34) are not cured. For this reason, occurrence of a problem in which the adhesive layer 32 remains on the semiconductor device main body parts 21, and a problem in which the adhesive layer 32 intrudes into the semiconductor device main body parts 21 and the adhesive layer 32 is accordingly difficult to remove from the semiconductor device main body parts 21 can be reliably prevented. Moreover, since the protective film 30 is attached to the outer peripheral portions of the respective semiconductor devices 20, no problem arises when the second face 10B of the semiconductor substrate 10 is ground or polished.

In addition, during the dicing process, when the semiconductor substrate 10 is ground and individualized while a rotary blade causes water to flow, water containing various shavings flows on the surface of the semiconductor substrate. When the semiconductor devices 20 are not covered by the protective film 30, some of the shavings adhere to the semiconductor devices 20. Furthermore, contaminants also adhere to the semiconductor devices 20 during transport of the semiconductor substrate 10, transport or storage of the individualized semiconductor devices, or other processes. Particularly, during the dicing process, chipping easily occurs in the semiconductor substrate 10, and shavings of the semiconductor substrate 10 are easily generated. In addition, chipping easily occurs in the semiconductor substrate 10, and shavings of the semiconductor substrate 10 are easily generated due to contact between the semiconductor devices. When the semiconductor device 20 is constituted by a solid-state imaging element, contaminants and shavings adhering to the semiconductor devices 20 cause generation of image defects such as white and black spots in a following imaging test of the solid-state imaging element, and accordingly cause a drop of a manufacturing yield of the solid-state imaging element.

In Example 1, since the semiconductor devices 20 are covered by the protective film 30 during dicing, the problems described above do not arise. In addition, adhesion of contaminants and shavings to the semiconductor devices 20 during transport of the semiconductor substrate 10, transport or storage of the individualized semiconductor devices 20, and other processes can be reliably prevented. In addition, the portions of the adhesive layer 32 of the protective film 30 coming into contact with the semiconductor device main body parts 21 are in the cured state. For this reason, the semiconductor devices 20 are not adversely affected by the adhesive layer 32 even when peeling of the protective film 30 is performed in the final stage of the manufacturing process of the semiconductor device, or when the semiconductor devices 20 are stored for a long period of time. Moreover, when the semiconductor devices 20 are attracted or held by collets in the state shown in, for example, [Step-150], occurrence of damage to the semiconductor devices 20 can be reliably prevented, and adhesion of contaminants generated during attraction and holding by the collets (for example, shavings of the semiconductor substrate) to the semiconductor devices 20 can be prevented.

Generally, in [Step-100], a defect and non-defect evaluation test is performed on semiconductor devices when manufacturing of the semiconductor devices 20 is completed so as to determine defective and non-defective products. The yield of the semiconductor devices 20 at this moment is assumed to be Y₁. In addition, when the semiconductor devices are finally assembled as will be described later, in other words, when the semiconductor devices 20 are housed in a package to have a form of a final product, a test for evaluating the characteristics and defects and non-defects of a semiconductor device assembled product as a final product are performed so as to determine the product to be a defective product or a non-defective product. The yield of the semiconductor devices 20 in the form of a final product at that time is assumed to be Y₂. Here, if contaminants or the like adhere to the semiconductor devices 20 from when the semiconductor devices 20 are manufactured to when the semiconductor devices 20 have the form of a final product, and thereby cause the semiconductor devices 20 to be defective, a significant difference is generated between the yield Y₁ and the yield Y₂. Thus, in the related art, such a difference (drop) of yields is anticipated, and the manufacturing amount of the semiconductor devices 20 is decided based on a prediction of a drop in the yield. However, in Example 1, a drop in the yield attributable to adhesion of contaminants, or the like to the semiconductor devices 20 from when the semiconductor devices 20 are manufactured to when the semiconductor devices 20 have the form of a final product can be prevented, and thus neither such a prediction of yields, nor wasteful production based on expectation of defective products is necessary. In addition, this technology contributes to advancing delivery dates, just-in-time production, a reduction in total manufacturing cost for the semiconductor devices 20, simplifying manufacturing facilities, a reduction in man-hours for management, and the like. The same effects are exhibited also in a number of Examples described below.

### Example 2

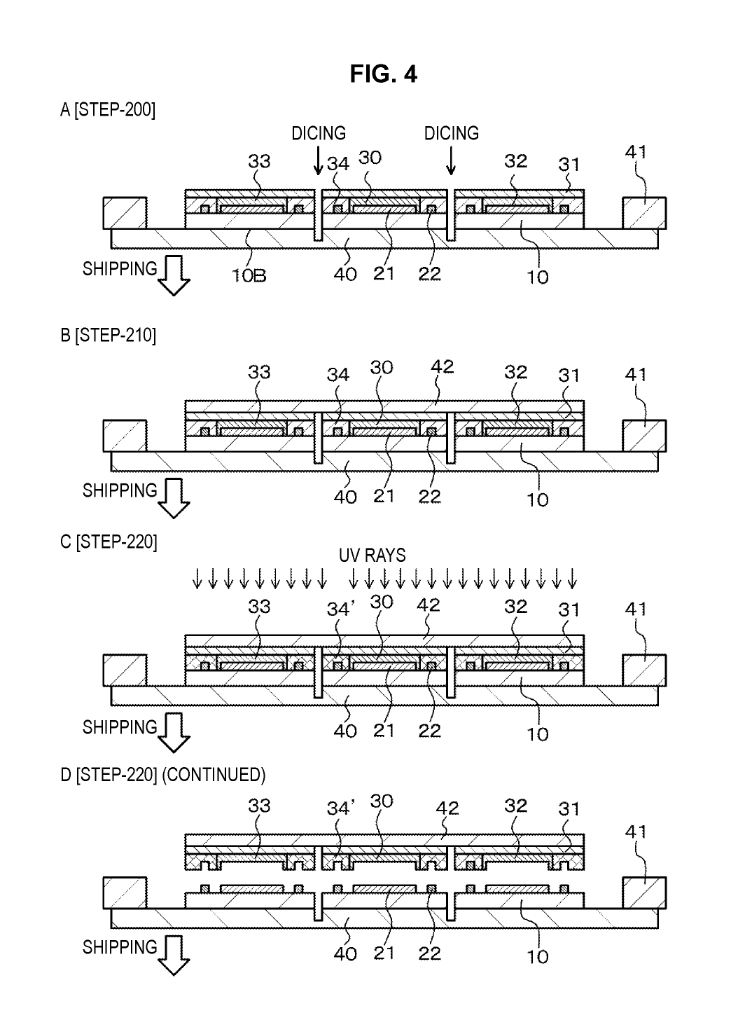

Example 2 is a modification of Example 1. FIGS. 4A, 4B, 4C, and 4D show schematic end face views of the semiconductor substrate, and the like, for describing a processing method of a semiconductor substrate of Example 2. Hereinafter, the processing method of a semiconductor substrate of Example 2 will be described with reference to the drawings, and FIG. 19 that is a flowchart for describing the processing method of a semiconductor substrate.

[Step-200]

First, the same steps as [Step-100] to [Step-150] of Example 1 are executed (See FIG. 4A).

[Step-210]

After the protective film 30 and the semiconductor substrate 10 are diced as described above, the peeling film 42 is attached onto the protective film 30 (See FIG. 4B). When requested by a client, the semiconductor substrate is shipped in the state as shown in FIG. 4B.

[Step-220]

Next, the non-cured portions 34 of the adhesive layer 32 are cured by radiating UV rays on the protective film 30 via the peeling film 42, and adhesiveness of the adhesive layer 32 is thereby reduced (See FIG. 4C). Then, the protective film 30 is peeled (See FIG. 4D). When requested by a client, the semiconductor substrate is shipped in the state as shown in FIG. 4C or 4D.

### Example 3

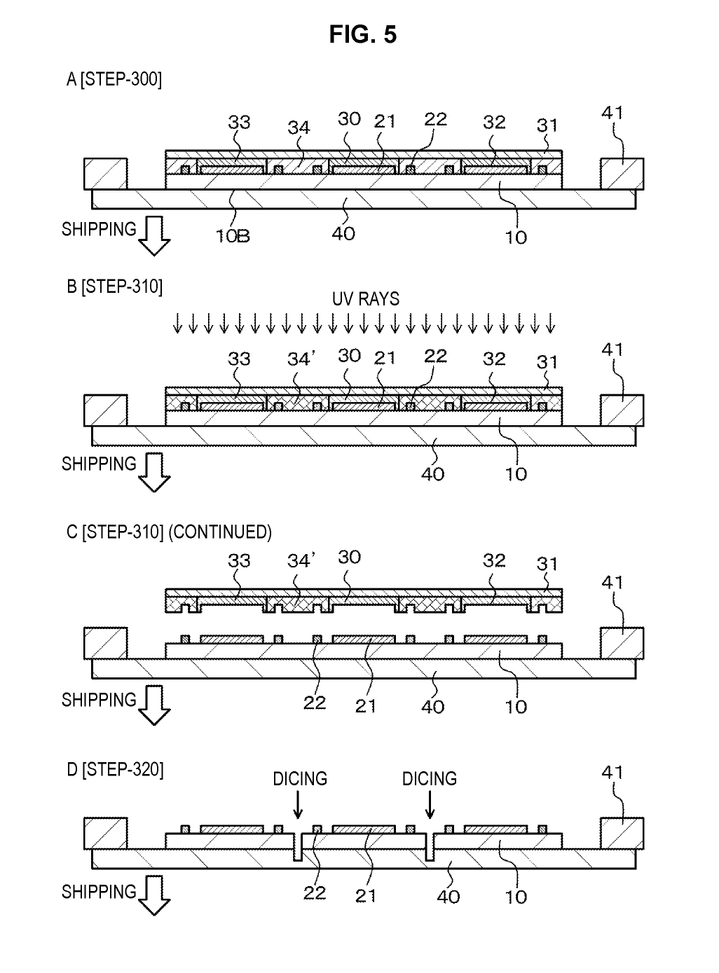

Example 3 is also a modification of Example 1. FIGS. 5A, 5B, 5C, and 5D show schematic end face views of the semiconductor substrate and the like for describing a processing method of a semiconductor substrate of Example 3. Hereinafter, the processing method of a semiconductor substrate of Example 3 will be described with reference to the drawings, and FIG. 19 that is a flowchart for describing the processing method of a semiconductor substrate.

[Step-300]

First, the same steps as [Step-100] to [Step-140] of Example 1 are executed (See FIG. 5A).

[Step-310]

Then, the non-cured portions 34 of the adhesive layer 32 are cured by radiating UV rays on the protective film 30, and adhesiveness of the adhesive layer 32 is thereby reduced (See FIG. 5B). Next, the protective film 30 is peeled (See FIG. 5C). When requested by a client, the semiconductor substrate is shipped in the state as shown in FIG. 5B or 5C.

[Step-320]

Then, the semiconductor substrate 10 is diced in the same manner as in [Step-150] of Example 1.

### Example 4

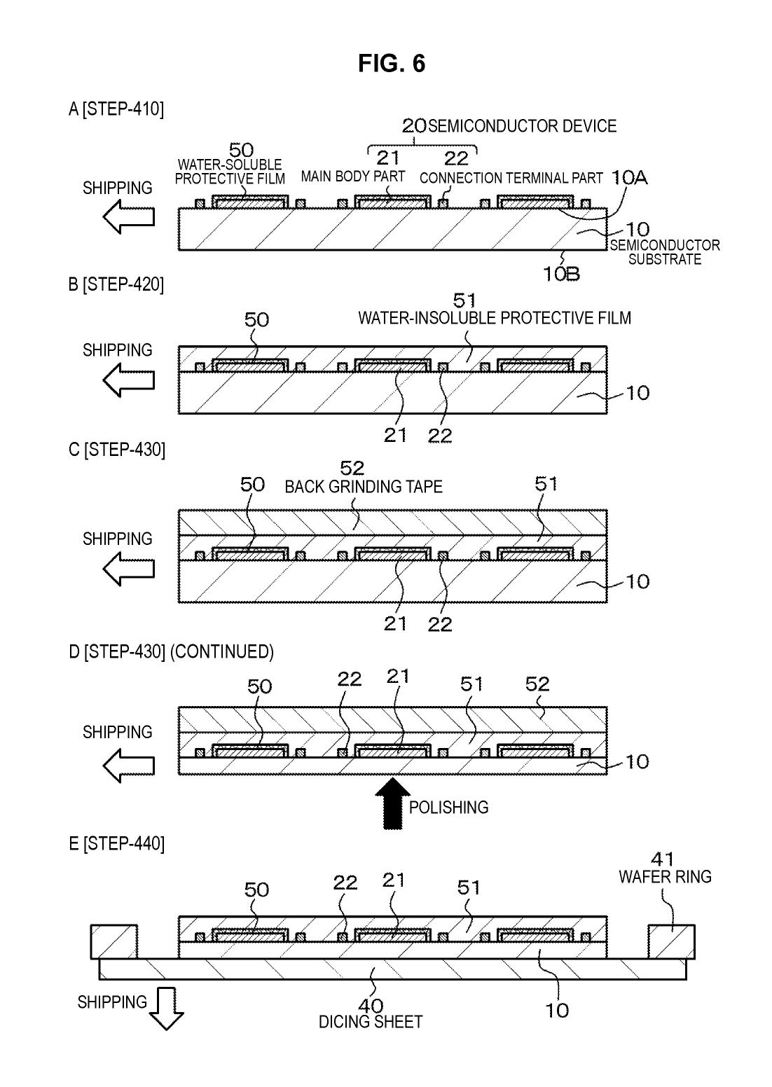

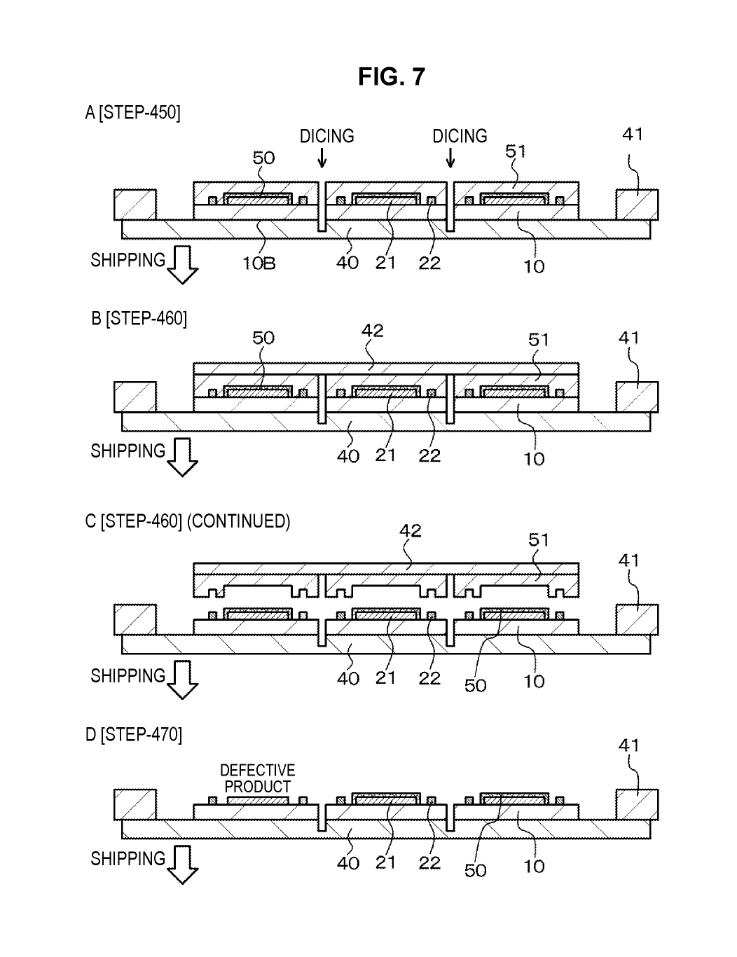

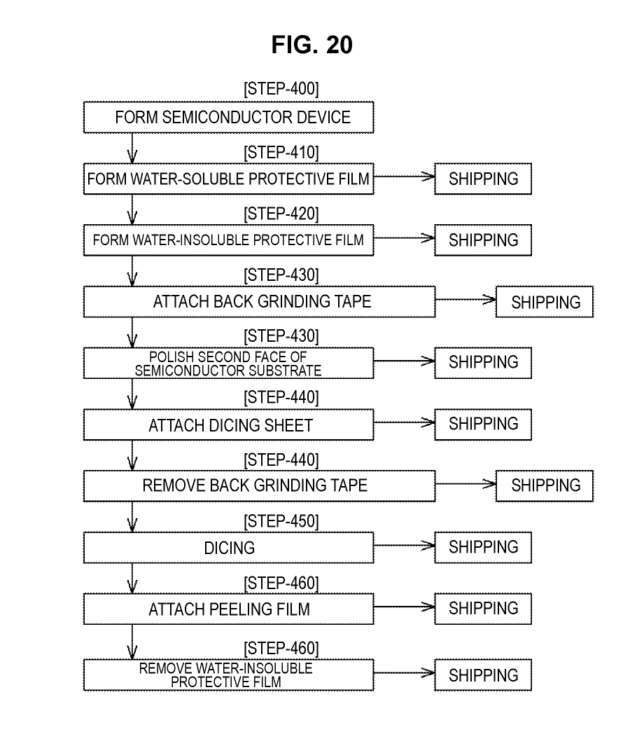

Example 4 relates to the processing method of a semiconductor substrate according to the second embodiment of the present disclosure, and the processed semiconductor substrate product according to the second embodiment of the present disclosure. FIGS. 6A, 6B, 6C, 6D, 7A, 7B, 7C, and 7D show schematic end face views of the semiconductor substrate and the like for describing a processing method of a semiconductor substrate of Example 4. Hereinafter, the processing method of a semiconductor substrate and a processed semiconductor substrate product of Example 4 will be described with reference to the drawings, and FIG. 20 that is a flowchart for describing the processing method of a semiconductor substrate.

[Step-400]

First, the plurality of semiconductor devices 20, each of which includes the semiconductor device main body part 21 (specifically, an imaging unit) and the connection terminal parts 22, are formed on the first face 10A of the semiconductor substrate 10 in the state in which the semiconductor devices are separated from each other, using a method in the related art in the same manner as in [Step-100] of Example 1. Then, a characteristic evaluation test is performed on the semiconductor devices 20.

[Step-410]

Next, a water-soluble protective film 50 is formed on the semiconductor device main body parts 21 except for the regions of the first face 10A of the semiconductor substrate 10 on which the semiconductor devices 20 are not formed and the connection terminal parts 22 (See FIG. 6A). To be specific, the water-soluble protective film 50 can be formed over the semiconductor device main body parts 21 by applying an aqueous polyvinyl alcohol (PVA) solution to the semiconductor device main body parts 21 using, for example, an ink jet printing method or a screen printing method, and then drying the solution. It should be noted that, with regard to a forming pattern of the water-soluble protective film 50, the solution may be applied to the semiconductor device main body parts 21 after the formation positions of the semiconductor device main body parts 21 on the semiconductor substrate 10 are confirmed through an image, or may be applied to the semiconductor device main body parts 21 after the forming pattern thereof is stored and the formation positions of the semiconductor device main body parts 21 on the semiconductor substrate 10 are confirmed through an image. The water-soluble protective film 50 may be preferably formed even on the portion that comes into contact with the collets for push-up. Since the semiconductor substrate 10 is cut for individualization while water flows in the dicing process, the water-soluble protective film 50 is not supposed to be formed in the vicinity of a scribe line.

In this manner, a processed semiconductor substrate product can be obtained as shown in FIG. 6A, the product including:

(a) the semiconductor substrate 10 having the first face 10A on which the plurality of semiconductor devices 20, each of which includes the semiconductor device main body part 21 and the connection terminal parts 22, are formed in the state in which the devices are separated from each other; and

(b) the water-soluble protective film 50 formed on the semiconductor device main body parts 21 except for the regions of the first face 10A of the semiconductor substrate 10 on which the semiconductor devices 20 are not formed and the connection terminal parts 22.

It should be noted that the outer edge of the water-soluble protective film 50 is indicated by a dashed line in FIG. 13A.

When requested by a client, the semiconductor substrate is shipped in the state as shown in FIG. 6A.

[Step-420]

Then, a water-insoluble protective film 51 that includes an acrylic resin is formed on the water-soluble protective film 50, the connection terminal parts 22, and the first face 10A of the semiconductor substrate 10 using the screen printing method (See FIG. 6B). When requested by a client, the semiconductor substrate is shipped in the state as shown in FIG. 6B.

[Step-430]

Next, a back grinding tape 52 is attached onto the water-insoluble protective film 51 (See FIG. 6C). Then, the second face 10B of the semiconductor substrate 10 opposite to the first face 10A of the semiconductor substrate 10 is polished in the same manner as in [Step-130] of Example 1 (See FIG. 6D). When requested by a client, the semiconductor substrate is shipped in the state as shown in FIG. 6C or 6D.

[Step-440]

Next, after the dicing sheet 40 is attached to the second face 10B of the semiconductor substrate 10 in the same manner as in [Step-140] of Example 1, the back grinding tape 52 is removed (See FIG. 6E). When requested by a client, the semiconductor substrate is shipped in the state as shown in FIG. 6E.

[Step-450]

Then, the semiconductor substrate 10 is diced in the same manner as in [Step-150] of Example 1 (See FIG. 7A). When requested by a client, the semiconductor substrate is shipped in the state as shown in FIG. 7A.

[Step-460]

Next, the peeling film 42 is attached onto the water-insoluble protective film 51 (See FIG. 7B), and the peeling film 42 and the water-insoluble protective film 51 are removed from the water-soluble protective film 50 (See FIG. 7C) in the same manner as in [Step-160] of Example 1. The water-soluble protective film 50 is removed in a following step using, for example, warm water. Alternatively, the water-insoluble protective film 51 can be removed by being peeled or dissolved using, for example, a solvent, depending on the water-insoluble protective film 51.

It should be noted that the semiconductor substrate 10 is carried in a characteristic evaluation device to evaluate the characteristics of the semiconductor devices 20. Then, predetermined electric characteristic evaluation is performed on individual semiconductor devices by bringing a measuring probe into contact with the connection terminal parts 22 of each semiconductor device 20, and thereby determination of defective and non-defective products is made. When a semiconductor device is constituted by a solid-state imaging element, evaluation may be performed using light radiation for characteristic evaluation.

[Step-470]

Depending on cases, the water-soluble protective film 50 of a defective product is removed using, for example, warm water (See FIG. 7D). Accordingly, a defective semiconductor device 20 can be clearly identified.

As described above, in Example 4, since the water-soluble protective film 50 is formed on the semiconductor device main body parts 21 except for the regions of the first face 10A of the semiconductor substrate 10 on which the semiconductor devices 20 are not formed and the connection terminal parts 22, tests for evaluating the characteristics and defects or non-defects of the semiconductor devices 20 can be performed while preventing adhesion of contaminants and the like to the semiconductor device main body parts 21. Moreover, since the water-soluble protective film 50 is formed on the semiconductor device main body parts 21, the occurrence of problems of residual adhesive in which the water-soluble protective film 50 remains on the semiconductor device main body parts 21 and in which the water-soluble protective film 50 is difficult to remove can be reliably prevented in following manufacturing processes, and no problems arise during grinding or polishing of the second face 10B of the semiconductor substrate 10 either. In addition, since the water-soluble protective film 50 is covered by the water-insoluble protective film 51 in the dicing process, the water-soluble protective film 50 is not removed when the semiconductor substrate 10 is cut for individualization while water flows using a rotary blade, and shavings do not adhere to the semiconductor devices 20 in the dicing process. Furthermore, the semiconductor devices 20 are not adversely affected by the water-soluble protective film 50 even when the semiconductor devices 20 are stored for a long period of time, or when the water-soluble protective film 50 is removed in the final stage of the manufacturing process. Additionally, when the semiconductor devices 20 are attracted and held by the collets in the state described in [Step-470], damage to the semiconductor devices 20 can be reliably avoided, and adhesion of contaminants (for example, shavings of the semiconductor substrate) generated when the collets attract and hold the semiconductor devices 20 can be prevented.

### Example 5

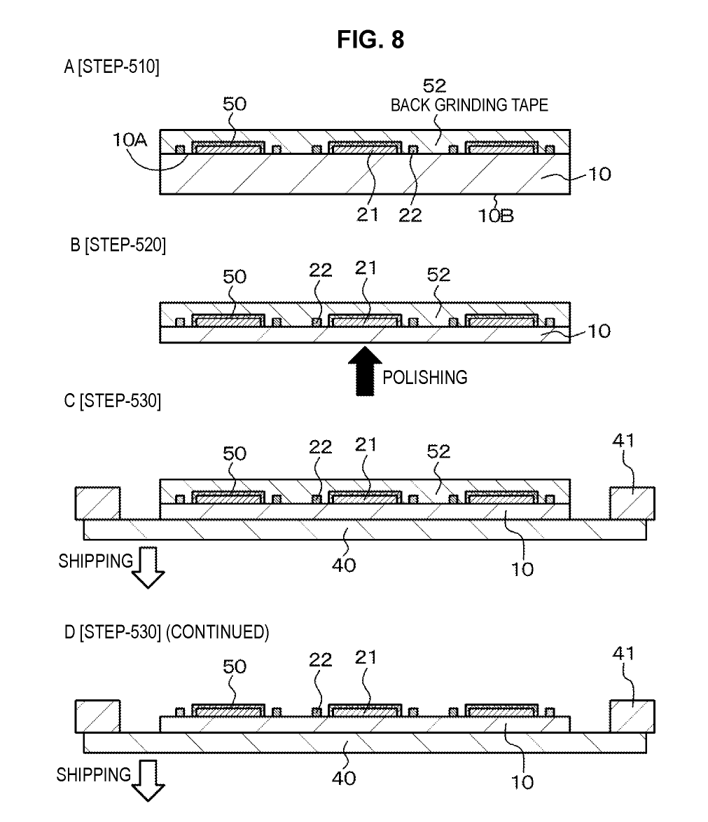

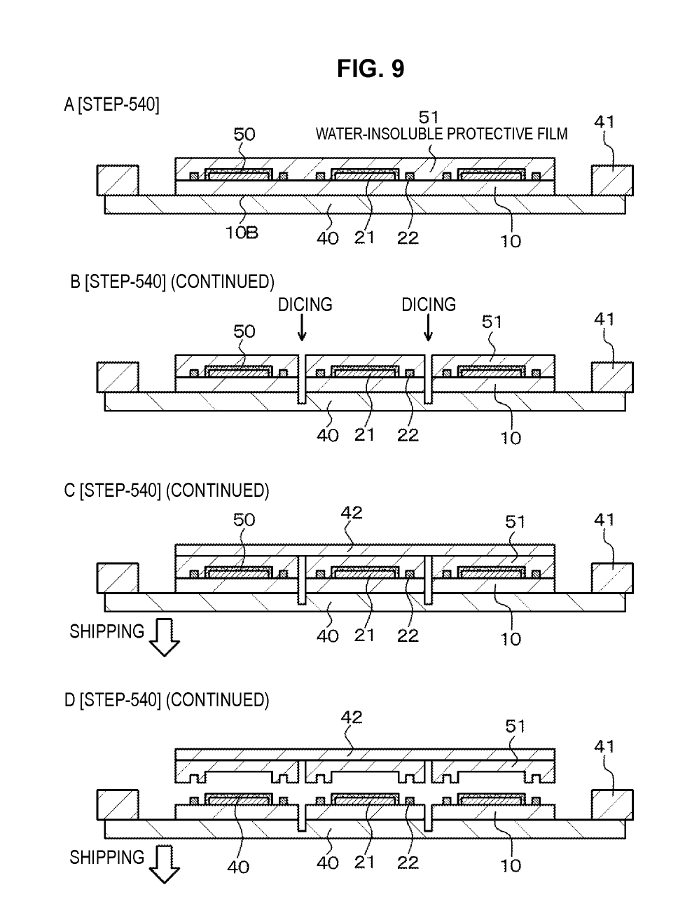

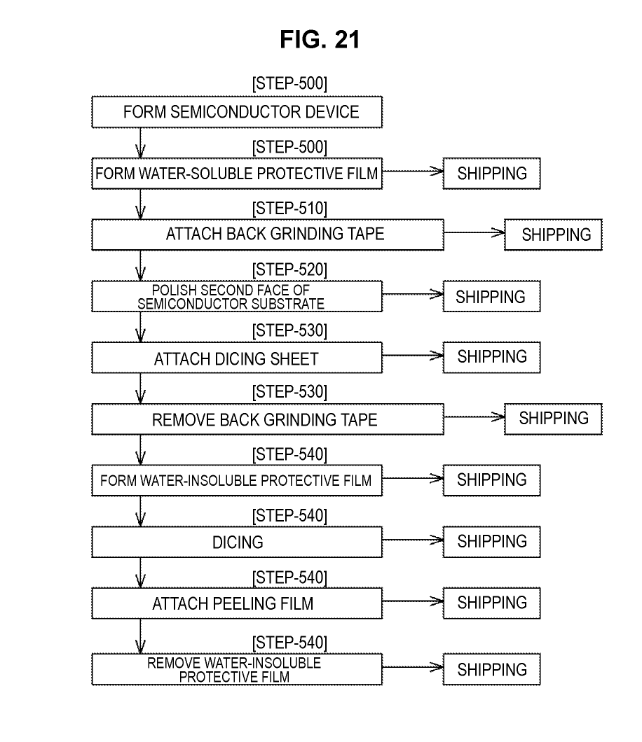

Example 5 is a modification of Example 4. FIGS. 8A, 8B, 8C, 8D, 9A, 9B, 9C, and 9D show schematic end face views of the semiconductor substrate, and the like for describing a processing method of a semiconductor substrate of Example 5. Hereinafter, the processing method of a semiconductor substrate of Example 5 will be described with reference to the drawings, and FIG. 21 that is a flowchart for describing the processing method of a semiconductor substrate.

[Step-500]

First, the same steps as [Step-400] and [Step-410] of Example 4 are executed.

[Step-510]

Then, the back grinding tape 52 is attached onto the water-soluble protective film 50, the connection terminal parts 22, and the first face 10A of the semiconductor substrate 10 (See FIG. 8A).

[Step-520]

Next, the second face 10B of the semiconductor substrate 10 opposite to the first face 10A is polished in the same manner as in [Step-130] of Example 1 (See FIG. 8B).

[Step-530]

Then, the dicing sheet 40 is attached to the second face 10B of the semiconductor substrate 10 in the same manner as in [Step-140] of Example 1 (See FIG. 8C). The back grinding tape 52 is removed (See FIG. 8D). When requested by a client, the semiconductor substrate is shipped in the state as shown in FIG. 8C or 8D.

[Step-540]

Next, the water-insoluble protective film 51 is formed on the water-soluble protective film 50, the connection terminal parts 22, and the first face 10A of the semiconductor substrate 10 (See FIG. 9A), the semiconductor substrate 10 is diced (See FIG. 9B), the peeling film 42 is attached onto the water-insoluble protective film 51 (See FIG. 9C), and then the peeling film 42 and the water-insoluble protective film 51 are removed from the water-soluble protective film 50 (See FIG. 9D). To be specific, the same steps as [Step-420], [Step-450], and [Step-460] of Example 4 may be executed, and further the same step as [Step-470] of Example 4 may be executed. It should be noted that the water-insoluble protective film 51 can be removed by being peeled or dissolved using, for example, a solvent, depending on the water-insoluble protective film 51.

It should be noted that the protective film 30 may be removed after the same steps as [Step-110] to [Step-140] of Example 1 are executed, instead of [Step-510] to [Step-530]. Alternatively, the same steps as [Step-110] to [Step-160] of Example 1 may be executed, instead of [Step-510] to [Step-540].

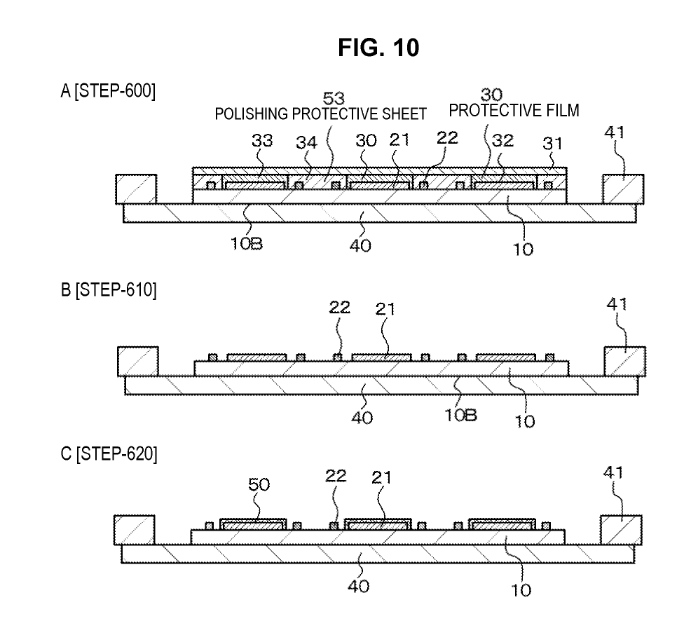

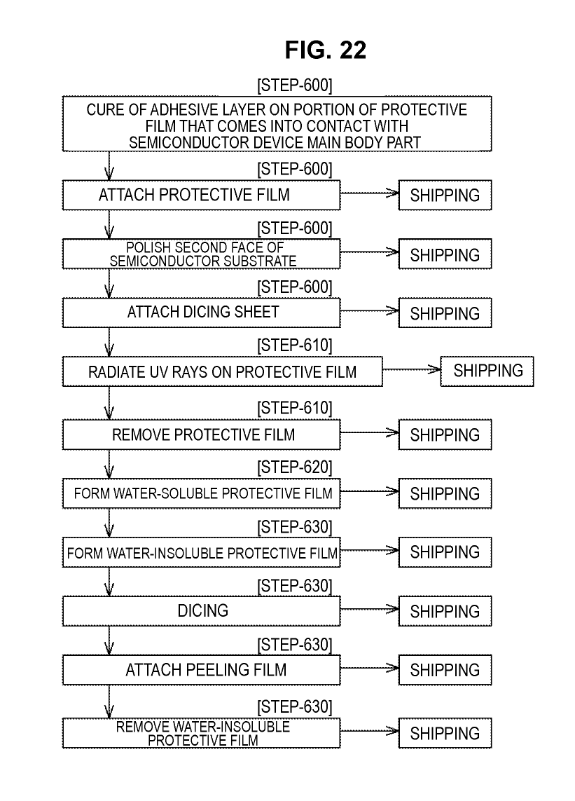

Example 6 relates to the processing method of a semiconductor substrate according to the third embodiment of the present disclosure, and the processed semiconductor substrate product according to the second embodiment of the present disclosure. FIGS. 10A, 10B, and 10C show schematic end face views of the semiconductor substrate and the like for describing a processing method of a semiconductor substrate of Example 6. Hereinafter, the processing method of a semiconductor substrate and the processed semiconductor substrate product of Example 6 will be described with reference to the drawings, and FIG. 22 that is a flowchart for describing the processing method of a semiconductor substrate.

[Step-600]

First, the plurality of semiconductor devices 20, each of which includes the semiconductor device main body part 21 (specifically, an imaging unit) and the connection terminal parts 22, are formed on the first face 10A of the semiconductor substrate 10 in the state in which the semiconductor devices are separated from each other using a method in the related art in the same manner as in [Step-100] of Example 1, and a test for evaluating the characteristics of the semiconductor devices 20 is performed. Next, a polishing protective sheet 53 that includes the protective film 30 is attached onto the semiconductor devices 20 and the first face 10A of the semiconductor substrate 10 in the same manner as in [Step-110] and [Step-120] of Example 1. Then, the second face 10b of the semiconductor substrate 10 opposite to the first face 10A of the semiconductor substrate 10 is polished in the same manner as in [Step-130] and [Step-140] of Example 1, and then the dicing sheet 40 is attached to the second face 10B of the semiconductor substrate 10 in the same manner as in [Step-140] of Example 1 (See FIG. 10A).

[Step-610]

Next, the polishing protective sheet 53 that includes the protective film 30 is peeled by radiating UV rays on the polishing protective sheet 53 that includes the protective film 30 to cure the adhesive layer 32 (See FIG. 10B) in the same manner as in [Step-160] of Example 1.

[Step-620]

Next, the water-soluble protective film 50 is formed on the semiconductor device main body parts 21 except for the regions of the first face 10A of the semiconductor substrate 10 on which the semiconductor devices 20 are not formed and the connection terminal parts 22 (See FIG. 10C) in the same manner as in [Step-410] of Example 4.

In this manner, the processed semiconductor substrate product can be obtained as shown in FIG. 10C, the product including:

(a) the semiconductor substrate 10 having the first face 10A on which the plurality of semiconductor devices 20, each of which includes the semiconductor device main body part 21 and the connection terminal parts 22, are formed in the state in which the semiconductor devices are separated from each other; and

(b) the water-soluble protective film 50 formed on the semiconductor device main body parts 21 except for the regions of the first face 10A of the semiconductor substrate 10 on which the semiconductor devices 20 are not formed, and the connection terminal parts 22.

[Step-630]

Then, the water-insoluble protective film 51 is formed on the water-soluble protective film 50, the connection terminal parts 22, and the first face 10A of the semiconductor substrate 10 (See FIG. 9A), the semiconductor substrate 10 is diced (See FIG. 9B), the peeling film 42 is attached onto the water-insoluble protective film 51 (See FIG. 9C), and then the peeling film 42 and the water-insoluble protective film 51 are removed from the water-soluble protective film 50 (see FIG. 9D). To be specific, the same steps as [Step-440] to [Step-460] of Example 4 may be executed, and further, the same step as [Step-470] of Example 4 may be executed. It should be noted that the water-insoluble protective film 51 can be removed by being peeled or dissolved using, for example, a solvent, depending on the water-insoluble protective film 51.

As described above, since the water-soluble protective film 50 is formed on the semiconductor device main body parts 21 except for the regions of the first face 10A of the semiconductor substrate 10 on which the semiconductor devices 20 are not formed, and the connection terminal parts 22 also in Example 6, tests for evaluating the characteristics, and defects or non-defects of the semiconductor devices 20 can be performed while preventing adhesion of contaminants or the like to the semiconductor device main body parts 21. Moreover, since the water-soluble protective film 50 is formed on the semiconductor device main body parts 21, the occurrence of problems of residual adhesive in which the water-soluble protective film 50 remains on the semiconductor device main body parts 21 and in which the water-soluble protective film 50 is difficult to remove can be reliably prevented in the following manufacturing processes. Furthermore, the semiconductor devices 20 are not adversely affected by the water-soluble protective film 50 even when the semiconductor devices 20 are stored for a long period of time, or when the water-soluble protective film 50 is peeled in the final stage of the manufacturing process. Additionally, when the semiconductor devices 20 are attracted and held by the collets after [Step-630], damage to the semiconductor devices 20 can be reliably avoided, and adhesion of contaminants (for example, shavings of the semiconductor substrate) generated when the collets attract and hold the semiconductor devices 20 can be prevented. In addition, various advantages described in Example 1 can be obtained by using the protective film 30 described in Example 1 as the polishing protective sheet 53.

### Example 7

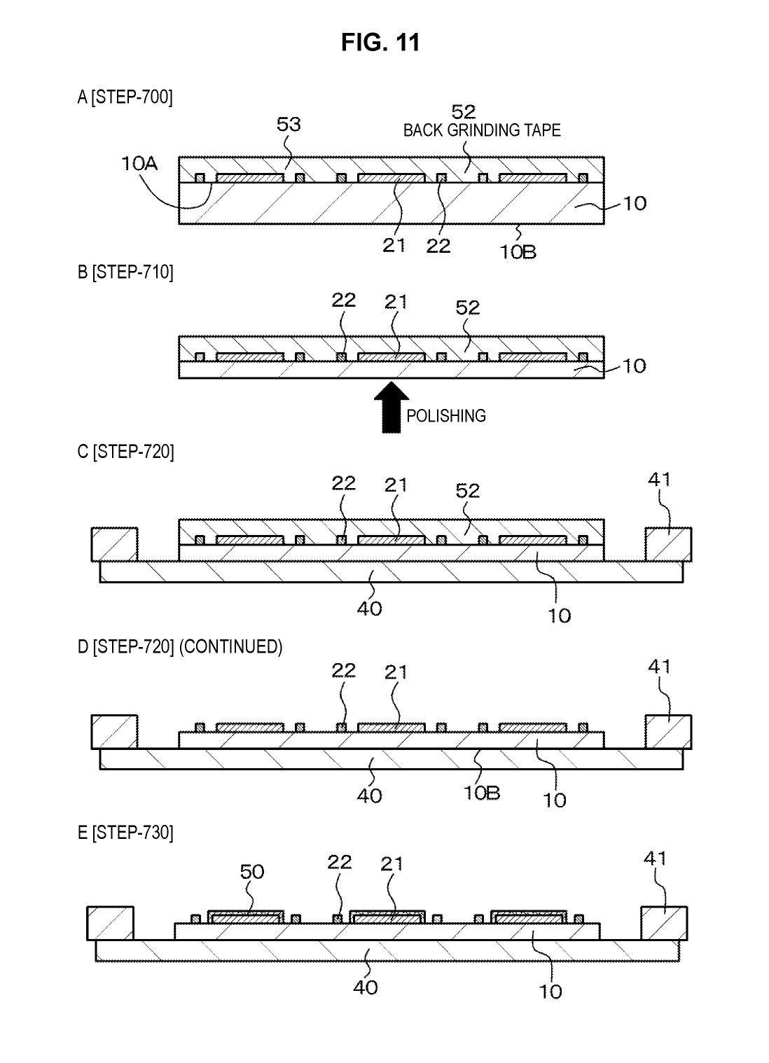

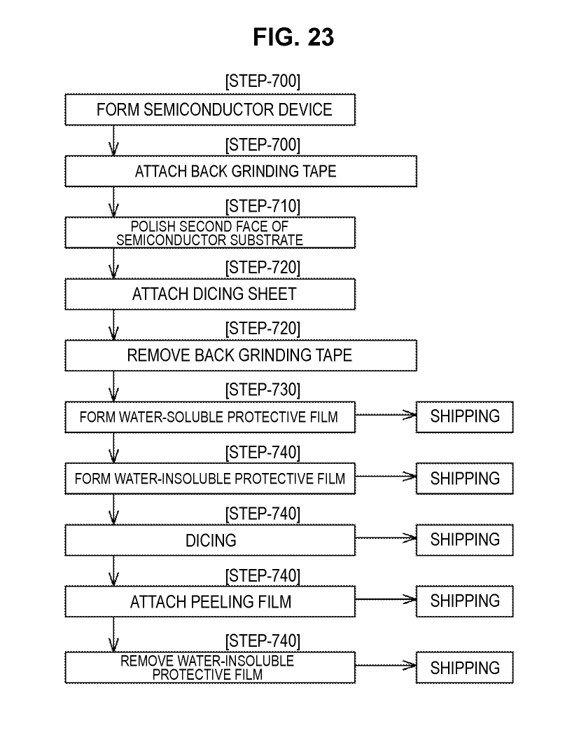

Example 7 is a modification of Example 6. In Example 6, the protective film 30 is configured to be a polishing protective sheet 53. Meanwhile, the back grinding tape 52 is configured to be the polishing protective sheet 53 in Example 7. FIGS. 11A, 11B, 11C, 11D, and 11E show schematic end face views of the semiconductor substrate, and the like for describing a processing method of a semiconductor substrate of Example 7. Hereinafter, the processing method of a semiconductor substrate of Example 7 will be described with reference to the drawings, and FIG. 23 that is a flowchart for describing the processing method of a semiconductor substrate.

[Step-700]

First, the plurality of semiconductor devices 20, each of which includes the semiconductor device main body part 21 (specifically, an imaging unit) and the connection terminal parts 22, are formed on the first face 10A of the semiconductor substrate 10 in the state in which the semiconductor devices are separated from each other using a method in the related art in the same manner as in [Step-100] of Example 1, and a test for evaluating the characteristics of the semiconductor devices 20 is performed. Then, the back grinding tape 52 is attached onto the semiconductor device main body parts 21, the connection terminal parts 22, and the first face 10A of the semiconductor substrate 10 (See FIG. 11A).

[Step-710]

Next, the second face 10B of the semiconductor substrate 10 opposite to the first face 10A is polished in the same manner as in [Step-130] of Example 1 (See FIG. 11B).

[Step-720]

Then, the dicing sheet 40 is attached onto the second face 10B of the semiconductor substrate 10 in the same manner as in [Step-140] of Example 1 (See FIG. 11C), and then the back grinding tape 52 is removed (See FIG. 11D).

[Step-730]

Next, the water-soluble protective film 50 is formed on the semiconductor device main body parts 21 except for the regions of the first face 10A of the semiconductor substrate 10 on which the semiconductor devices 20 are not formed, and the connection terminal parts 22 (See FIG. 11E) in the same manner as in [Step-410] of Example 4.

[Step-740]

Then, in the same manner as in [Step-630] of Example 6, the water-insoluble protective film 51 is formed on the water-soluble protective film 50, the connection terminal parts 22, and the first face 10A of the semiconductor substrate 10 (See FIG. 9A), the semiconductor substrate 10 is diced (See FIG. 9B), the peeling film 42 is attached onto the water-insoluble protective film 51 (See FIG. 9C), and then the peeling film 42 and the water-insoluble protective film 51 are removed from the water-soluble protective film 50 (see FIG. 9D). To be specific, the same steps as [Step-440] to [Step-460] of Example 4 may be executed, and further, the same step as [Step-470] of Example 4 may be executed.

### Example 8

Example 8 relates to a combination of the processing method of a semiconductor substrate according to the first embodiment of the present disclosure and the processing method of a semiconductor substrate according to the third embodiment of the present disclosure. To be specific, [Step-620] and the following steps of Example 6 are executed, or [Step-730] and the following steps of Example 7 are executed after [Step-160] of Example 1, after [Step-220] of Example 2, or after [Step-320] of Example 3.

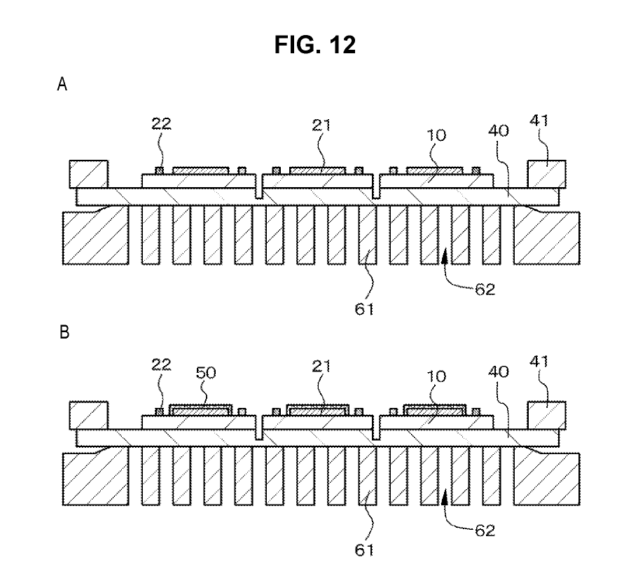

However, in such cases, since the dicing sheet 40 subtly extends when [Step-620] of Example 6 or [Step-730] of Example 7 is executed, there is concern of the formation position of the water-soluble protective film 50 subtly deviating on the semiconductor device main body parts 21. Thus, the dicing sheet 40 to which the semiconductor devices 20 are attached is mounted on a mounting table 61 as shown in FIG. 12A showing a schematic end face view of the semiconductor substrate, and the like. The mounting table 61 is provided with a number of hole parts 62, and the dicing sheet 40 is vacuum-attracted to the mounting table 61. In addition, in this state, the positions of the semiconductor device main body parts 21 are obtained using an imaging camera, and an ink jet printer is controlled based on the corresponding position information to form the water-soluble protective film 50 on the semiconductor device main body parts 21 (See FIG. 12B). In this manner, the water-soluble protective film 50 can be formed on the semiconductor device main body parts 21 with accuracy. It should be noted that the water-soluble protective film 50 can be formed on the semiconductor device main body parts 21 by controlling the ink jet printer based on position information of the semiconductor device main body parts 21 stored in advance without obtaining the positions of the semiconductor device main body parts 21 to the extent that there is no problem in accuracy.

In addition, the water-soluble protective film 50 may also be formed on the semiconductor device main body parts 21 by vacuum-attracting a support sheet to the mounting table 61 after the semiconductor substrate is transferred to the support sheet (to be described later) from the dicing sheet 40.

### Example 9

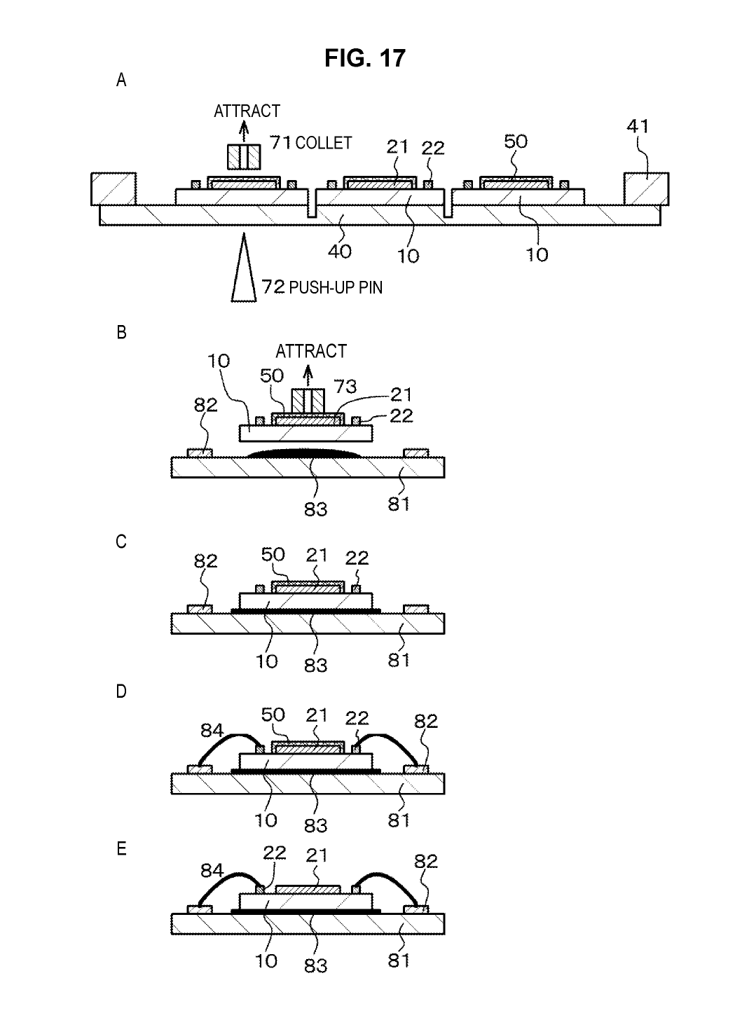

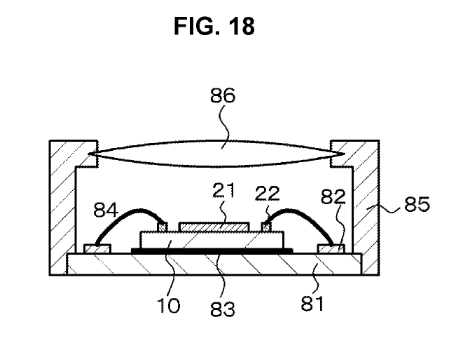

Example 9 is a modification of Examples 1 to 8, and relates to a process up to a step in which each individualized semiconductor device 20 obtained in Examples 1 to 8 is housed in a package so as to be in the form of a final product. Hereinafter, a manufacturing method of a semiconductor device of Example 9 will be described with reference to FIGS. 17A, 17B, 17C, 17D, and 18. It should be noted that, in the following description, the water-soluble protective film 50 is assumed to remain on the semiconductor device main body parts 21, but the protective film 30 may be assumed to remain on the semiconductor device main body parts 21.

With regard to the semiconductor devices 20 obtained in Examples 1 to 8, the diced semiconductor substrate 10 is carried to a chip mounting device while fixed to the wafer ring 41. Then, in a state in which UV rays are radiated on the dicing sheet 40 so as to reduce adhesion strength thereof, the dicing sheet 40 is pushed up using a needle-like push-up pin 72 from the back side while being pulled, and then partially peeled. Then, the individualized (individually divided) semiconductor devices 20 are attracted and held by collets 71. In this manner, the semiconductor devices 20 are picked up from the dicing sheet 40, and transferred onto a support sheet attached to another wafer ring (this state is not shown). When requested by a client, the semiconductor substrate is shipped in this state.

Then, the following operations are generally performed in another factory at a client's discretion. In other words, the semiconductor substrate 10 is carried into a chip mounting device while fixed to the wafer ring 41. Then, in a state in which UV rays are radiated on the support sheet so as to reduce adhesion strength, the support sheet is pushed up using a needle-like push-up pin from the back side while being pulled, and then partially peeled. Then, the individualized semiconductor devices 20 are attracted and held by collets 73. In this manner, the semiconductor devices 20 are picked up from the support sheet, and placed on an adhesive 83 applied onto a transfer part on a printed wiring board 81 (See FIGS. 17B and 17C). Then, the adhesive 83 is cured by being heated, radiated with UV rays, or the like, to fix the semiconductor devices 20 onto the printed wiring board 81. Next, the connection terminal parts 22 of the semiconductor devices 20 are electrically connected to terminal parts 82 provided on the printed wiring board 81 using wire bonders 84, or the like (See FIG. 17D). It should be noted that this connection can also be referred to as a flip-chip connection. Then, the water-soluble protective film 50 is removed using, for example, water or warm water (See FIG. 17E). It should be noted that various contaminants and shavings are also cleaned as the same time as the removal of the water-soluble protective film 50. Then, a sealing resin is applied to opening parts of a package 85, a lens is mounted thereon, and then the sealing resin is cured, and accordingly, a semiconductor device can be completed as a final product (See FIG. 18).

During push-up of a semiconductor device, if the collets 71 and 73 for push-up directly touch the semiconductor device main body part 21, there is a problem in that damage is left on the semiconductor device main body part 21. Normally, it is desirable for the collets 71 and 73 to be brought into contact with the semiconductor device main body part 21 that has the largest area to attract and hold the semiconductor devices during push-up of the semiconductor devices. However, if damage is left on the semiconductor device main body part 21, for example, an image defect is made in an image, resulting in a defective final product. For this reason, the collets 71 and 73 are brought into contact with a portion other than the semiconductor device main body part 21 in the related art. Thus, as semiconductor devices have become miniaturized and wirings have become fine in recent years, the area of such a portion other than the semiconductor device main body part 21 has become small, and accordingly, the area that the collets 71 and 73 can touch has become narrow. Bringing the collets 71 and 73 to the connection terminal parts 22 can also be considered, but as an operation voltage of a semiconductor device has been lowered in recent years, a withstand voltage that prevents electrostatic breakdown is lowered, and if the collets 71 and 73 are brought into contact with the connection terminal parts 22, electrostatic breakdown easily occurs, resulting in a defective operation, and accordingly, the yield of final semiconductor device products declines. Decreasing the area in which the collets 71 and 73 touch a semiconductor device 20 has also been reviewed, but if the area in which the collets 71 and 73 touch the semiconductor device 20 is excessively reduced, damage is easily left on the semiconductor device 20 when the collets 71 and 73 touch the semiconductor device 20, which also causes a defective operation. Particularly, in recent years, as the thickness of a protective film formed on the outermost surface of a semiconductor device has become thin, the occurrence of damage to a semiconductor device caused by the collets 71 and 73 has become a significant problem.

In Example 9, since the semiconductor devices 20 come into contact with the collets 71 and 73 via the protective film 30 or the water-soluble protective film 50, the occurrence of damage to the semiconductor device main body parts 21 can be reliably prevented. In addition, steps including and after the step for removing the protective film 30 and the water-soluble protective film 50 (for example, steps including and after the step shown in FIG. 17E) may be performed under a fairly clean environment, investment in facilities can be cut. It should be noted that rubber collets can also be used as the collets 71 and 73. In addition, the step for removing the protective film 30 or the water-soluble protective film 50 may be performed before the connection terminal parts 22 of a semiconductor device 20 are connected to the terminal parts 82 provided on the printed wiring board 81, or in an earlier step before the connection step.

### Example 10

In Example 10, a semiconductor device that is constituted by a solid-state imaging element will be described with reference to FIG. 13B that is a schematic cross-sectional view of two semiconductor devices (solid-state imaging elements).

A solid-state imaging element 100 that constitutes a semiconductor device 20 obtained in Examples 1 to 9 includes photoelectric converting elements (light-sensing elements) 111 and a polarizing element 121 provided on a light incident side of the photoelectric converting elements 111. It should be noted that the solid-state imaging element 100 includes the polarizing element 121 of two or more types having different polarizing azimuths. In adjacent solid-state imaging elements 100A and 100B, transmission axes of the polarizing elements 121A and 121B are orthogonal to each other. On-chip lenses 114 are disposed on the upper side of the photoelectric converting elements 111, and the polarizing element 121 is provided on the upper side of the on-chip lenses 114.

To be specific, the solid-state imaging element 100 is configured to include the photoelectric converting elements 111 provided on a silicon semiconductor substrate 110, and then laminating, on the substrate, a first planarization film 112, a wavelength selection layer (color filter layer 113), the on-chip lenses 114, a second planarization film 115, an inorganic insulating base layer 116, and the polarizing element 121. The first planarization film 112 and the inorganic insulating base layer 116 are formed of SiO₂, and the second planarization film 115 is formed of an acrylic resin. Each of the photoelectric converting elements 111 is formed of a CCD element, a CMOS image sensor, or the like. Reference numeral 117 is a light shielding unit provided in the vicinity of the photoelectric converting elements 111.

As the arrangement of solid-state imaging elements, for example, a Bayer array is employed. In other words, one pixel has one sub-pixel which senses red light, one sub-pixel which senses blue light, and two sub-pixels which sense green light, and each sub-pixel includes a solid-state imaging element. Pixels are arrayed in a two-dimensional matrix shape in a row direction and a column direction. First directions (to be described later) of all polarizing elements within one pixel are the same. Furthermore, first directions of polarizing elements in pixels arrayed in a row direction are all same. On the other hand, pixels in which first directions of polarizing elements are parallel with a row direction and pixels in which first directions of polarizing elements are parallel with a column direction are arranged in an alternate manner in the column direction.

In addition, the polarizing element 121 is formed by a plurality of apposed strip-like members, and functions as a wire grid polarizer. The direction in which the strip-like members extend (first direction) coincides with a polarizing azimuth in which light should be cancelled, and the direction in which the strip-like members repeat (which is a second direction orthogonal to the first direction) coincides with a polarizing azimuth in which light should transmit. In other words, out of light incident on the polarizing element 121, the polarizer attenuates a polarization wave having electric field components in the direction parallel to the direction in which the strip-like members extend (first direction), and causes a polarization wave having electric field components in the direction orthogonal to the direction in which the strip-like members extend (second direction) to transmit therethrough. The first direction is a light absorption axis of the polarizing element, and the second direction is a light transmission axis of the polarizing element. It should be noted that the arrangement state of the polarizing element 121 is an example, and is not limited to the above description.

If an adhesive layer intrudes between strip-like members of the polarizing element 121 configured as the wire grid polarizer, when the adhesive layer is cured by radiating UV rays thereon in order to peel the adhesive layer, there is concern of the adhesive layer not being removed from the strip-like members, or damage to the polarizing element 121 occurring, but in a semiconductor device described in Examples 1 to 9, the occurrence of such problems can be reliably prevented.

Hereinabove, the present disclosure has been described based on preferred examples, but the present disclosure is not limited thereto. The configurations, structures, compositions, and the like of the processed semiconductor substrate products, semiconductor devices, protective films, water-soluble protective films, and water-insoluble protective films described in Examples are merely examples, and can be appropriately modified. It is needless to say that the processing method of a semiconductor substrate of an embodiment of the present disclosure can be applied to processed semiconductor substrate products and semiconductor devices with a bump.

It should be understood by those skilled in the art that various modifications, combinations, sub-combinations and alterations may occur depending on design requirements and other factors insofar as they are within the scope of the appended claims or the equivalents thereof.

Additionally, the present technology may also be configured as below.

[1]<<Processing method of semiconductor substrate: first embodiment>>

A processing method of a semiconductor substrate including:

(A) curing an adhesive layer by radiating UV rays at least on portions of a protective film that come into contact with semiconductor device main body parts before the protective film on which a UV curable adhesive layer is formed is attached to the semiconductor substrate having a first face on which a plurality of semiconductor devices, each of which includes a semiconductor device main body part and connection terminal parts, are formed in a state in which the semiconductor devices are separate from each other; and then

(B) attaching non-cured portions of the adhesive layer of the protective film to an outer peripheral portion of the semiconductor substrate, and a region of the semiconductor substrate positioned between the semiconductor devices, and bringing cured portions of the adhesive layer of the protective film into contact with the semiconductor device main body parts.

[2] The processing method of a semiconductor substrate according to [1], further including:

polishing a second face of the semiconductor substrate opposite to the first face after step (B).

[3] The processing method of a semiconductor substrate according to [2], further including:

attaching a dicing sheet to the second face of the semiconductor substrate after the second face of the semiconductor substrate is polished.

[4] The processing method of a semiconductor substrate according to [3], further including:

dicing the protective film and the semiconductor substrate after the dicing sheet is attached to the second face of the semiconductor substrate.

[5] The processing method of a semiconductor substrate according to [4], further including:

curing the adhesive layer by radiating UV rays on the protective film and then peeling the protective film after the protective film and the semiconductor substrate are diced.

[6] The processing method of a semiconductor substrate according to [5], in which a peeling film is attached onto the protective film, and then the protective film is peeled after UV rays are radiated on the protective film.
[7] The processing method of a semiconductor substrate according to [5], in which, after the protective film and the semiconductor substrate are diced, a peeling film is attached onto the protective film before UV rays are radiated on the protective film, and when UV rays are radiated on the protective film, the UV rays are radiated on the protective film via the peeling film.
[8] The processing method of a semiconductor substrate according to [3], further including:

after the dicing sheet is attached to the second face of the semiconductor substrate, curing the adhesive layer by radiating UV rays on the protective film, and after the protective film is peeled, dicing the semiconductor substrate.

[9]<<Processing method of semiconductor substrate: second embodiment>>

A processing method of a semiconductor substrate, the method including:

(A) forming a plurality of semiconductor devices, each of which includes a semiconductor device main body part and connection terminal parts, on a first face of the semiconductor substrate in a state in which the semiconductor devices are separate from each other; and then

(B) forming a water-soluble protective film on semiconductor device main body parts except for a region of the first face of the semiconductor substrate on which the semiconductor devices are not formed, and the connection terminal parts.

[10] The processing method of a semiconductor substrate according to [9], further including:

(C) forming a water-insoluble protective film on the water-soluble protective film, the connection terminal parts, and the first face of the semiconductor substrate, subsequent to step (B).

[11] The processing method of a semiconductor substrate according to [10], further including:

polishing a second face of the semiconductor substrate opposite to the first face after step (C).

[12] The processing method of a semiconductor substrate according to [11], further including:

after the second face of the semiconductor substrate is polished, attaching a dicing sheet to the second face of the semiconductor substrate, and then dicing the semiconductor substrate.

[13] The processing method of a semiconductor substrate according to [12], further including:

after the semiconductor substrate is diced, attaching a peeling film onto the water-insoluble protective film, and then removing the peeling film and the water-insoluble protective film from the water-soluble protective film.

[14] The processing method of a semiconductor substrate described in [9], in which, subsequent to step (B), after a back grinding tape is attached onto the water-soluble protective film, the connection terminal parts, and the first face of the semiconductor substrate, a second face of the semiconductor substrate opposite to the first face thereof is polished.
[15] The processing method of a semiconductor substrate described in [14], in which, after the second face of the semiconductor substrate is polished, a dicing sheet is attached to the second face of the semiconductor substrate, and then the back grinding tape is removed.
[16] The processing method of a semiconductor substrate described in [15], in which, after the back grinding tape is removed, a water-insoluble protective film is formed on the water-soluble protective film, the connection terminal parts, and the first face of the semiconductor substrate.
[17] The processing method of a semiconductor substrate described in [16], in which, after the water-insoluble protective film is formed, the semiconductor substrate is diced.
[18] The processing method of a semiconductor substrate described in [17], in which, after the semiconductor substrate is diced, a peeling film is attached onto the water-insoluble protective film, and then the peeling film and the water-insoluble protective film are removed from the water-soluble protective film.
[19]<<Processing method of semiconductor substrate: third embodiment>>

A processing method of a semiconductor substrate, the method including:

(A) forming a plurality of semiconductor devices, each of which includes a semiconductor device main body part and connection terminal parts, on a first face of a semiconductor substrate in the state in which the semiconductor devices are separated from each other; then

(B) attaching a polishing protective sheet onto the semiconductor devices and the first face of the semiconductor substrate, polishing a second face of the semiconductor substrate opposite to the first face, attaching a dicing sheet to the second face of the semiconductor substrate, and removing the polishing protective sheet; and then

(C) forming a water-soluble protective film on semiconductor device main body parts except for a region of the first face of the semiconductor substrate on which the semiconductor devices are not formed, and the connection terminal parts.

[20] The processing method of a semiconductor substrate according to [19], further including:

(D) forming a water-insoluble protective film on the water-soluble protective film, the connection terminal parts, and the first face of the semiconductor substrate, subsequent to step (C).

[21] The processing method of a semiconductor substrate according to [20], further including:

dicing the semiconductor substrate, subsequent to step (D).

[22] The processing method of a semiconductor substrate according to [21], further including:

after the semiconductor substrate is diced, attaching a peeling film onto the water-insoluble protective film, and then removing the peeling film and the water-insoluble protective film from the water-soluble protective film.

[23] The processing method of a semiconductor substrate according to [19], further including:

dicing the semiconductor substrate between step (B) and step (C).

[24] The processing method of a semiconductor substrate according to [23], in which, after the semiconductor substrate is diced, a non-defective semiconductor device is transferred to a support sheet.
[25]<<Processed semiconductor substrate product: first embodiment>>

A processed semiconductor substrate product including:

(a) a semiconductor substrate having a first face on which a plurality of semiconductor devices, each of which includes a semiconductor device main body part and connection terminal parts, are formed in a state in which the semiconductor devices are separate from each other; and

(b) a protective film that is formed with a UV curable adhesive layer and that covers the first face of the semiconductor substrate,

wherein an adhesive layer is cured on portions of the protective film that come into contact with the semiconductor device main body parts, and

wherein an adhesive layer of the protective film attached to an outer peripheral portion of the semiconductor substrate, and a region of the semiconductor substrate positioned between the semiconductor devices is not cured.

[26] The processed semiconductor substrate product according to [25], wherein the protective film and the semiconductor substrate are diced.
[27]<<Processed semiconductor substrate product: second embodiment>>

A processed semiconductor substrate product including:

(a) a semiconductor substrate having a first face on which a plurality of semiconductor devices, each of which includes a semiconductor device main body part and connection terminal parts, are formed in a state in which the semiconductor devices are separate from each other; and

(b) a water-soluble protective film that is formed on semiconductor device main body parts except for a region of the first face of the semiconductor substrate on which the semiconductor devices are not formed, and the connection terminal parts.

[28] The processed semiconductor substrate product according to [27], wherein the water-soluble protective film and the semiconductor substrate are diced.
[29] The processed semiconductor substrate product according to [27], wherein a water-insoluble protective film is formed on the water-soluble protective film, the connection terminal parts, and the first face of the semiconductor substrate.
[30] The processed semiconductor substrate product according to [29], wherein the water-insoluble protective film, the water-soluble protective film, and the semiconductor substrate are diced.
[31] The processed semiconductor substrate product according to [27] to [30], in which the water-soluble protective film is formed in a portion that comes into contact with a collet.
[32] The processed semiconductor substrate product according to any one of [27] to [31], in which the water-soluble protective film is removed from a defective semiconductor device product.
[33] The processed semiconductor substrate product according to any one of [27] to [32], wherein a second face of the semiconductor substrate opposite to the first face is polished.
[34] The processed semiconductor substrate product according to [25] or [27], in which a dicing sheet is attached to a second face of the semiconductor substrate.
[35] The processed semiconductor substrate product according to [34], in which the semiconductor substrate is diced.

The present disclosure contains subject matter related to that disclosed in Japanese Priority Patent Application JP 2012-169604 filed in the Japan Patent Office on Jul. 31, 2012, the entire content of which is hereby incorporated by reference.

What is claimed is:

1. A processing method of a semiconductor substrate, the method comprising:
(A) curing an adhesive layer by radiating UV rays at least on portions of a protective film that come into contact with semiconductor device main body parts before the protective film on which a UV curable adhesive layer is formed is attached to the semiconductor substrate having a first face on which a plurality of semiconductor devices, each of which includes a semiconductor device main body part and connection terminal parts, are formed in a state in which the semiconductor devices are separate from each other; and then
(B) attaching non-cured portions of the adhesive layer of the protective film to an outer peripheral portion of the semiconductor substrate, and a region of the semiconductor substrate positioned between the semiconductor devices, and bringing cured portions of the adhesive layer of the protective film into contact with the semiconductor device main body parts.

2. The processing method of a semiconductor substrate according to claim 1, further comprising:
polishing a second face of the semiconductor substrate opposite to the first face after step (B).

3. The processing method of a semiconductor substrate according to claim 2, further comprising:
attaching a dicing sheet to the second face of the semiconductor substrate after the second face of the semiconductor substrate is polished.

4. The processing method of a semiconductor substrate according to claim 3, further comprising:
dicing the protective film and the semiconductor substrate after the dicing sheet is attached to the second face of the semiconductor substrate.

5. The processing method of a semiconductor substrate according to claim 4, further comprising:
curing the adhesive layer by radiating UV rays on the protective film and then peeling the protective film after the protective film and the semiconductor substrate are diced.

6. The processing method of a semiconductor substrate according to claim 3, further comprising:
after the dicing sheet is attached to the second face of the semiconductor substrate, curing the adhesive layer by radiating UV rays on the protective film, and after the protective film is peeled, dicing the semiconductor substrate.

7. A processing method of a semiconductor substrate, the method comprising:
(A) forming a plurality of semiconductor devices, each of which includes a semiconductor device main body part and connection terminal parts, on a first face of the semiconductor substrate in a state in which the semiconductor devices are separate from each other; and then
(B) forming a water-soluble protective film on semiconductor device main body parts except for a region of the first face of the semiconductor substrate on which the semiconductor devices are not formed, and the connection terminal parts.

8. The processing method of a semiconductor substrate according to claim 7, further comprising:
(C) forming a water-insoluble protective film on the water-soluble protective film, the connection terminal parts, and the first face of the semiconductor substrate, subsequent to step (B).

9. The processing method of a semiconductor substrate according to claim 8, further comprising:
polishing a second face of the semiconductor substrate opposite to the first face after step (C).

10. The processing method of a semiconductor substrate according to claim 9, further comprising:
after the second face of the semiconductor substrate is polished, attaching a dicing sheet to the second face of the semiconductor substrate, and then dicing the semiconductor substrate.

11. The processing method of a semiconductor substrate according to claim 10, further comprising:
after the semiconductor substrate is diced, attaching a peeling film onto the water-insoluble protective film, and then removing the peeling film and the water-insoluble protective film from the water-soluble protective film.

12. A processing method of a semiconductor substrate, the method comprising:
(A) forming a plurality of semiconductor devices, each of which includes a semiconductor device main body part and connection terminal parts, on a first face of a semiconductor substrate in the state in which the semiconductor devices are separated from each other; then
(B) attaching a polishing protective sheet onto the semiconductor devices and the first face of the semiconductor substrate, polishing a second face of the semiconductor substrate opposite to the first face, attaching a dicing sheet to the second face of the semiconductor substrate, and removing the polishing protective sheet; and then
(C) forming a water-soluble protective film on semiconductor device main body parts except for a region of the first face of the semiconductor substrate on which the semiconductor devices are not formed, and the connection terminal parts.

13. The processing method of a semiconductor substrate according to claim 12, further comprising:
(D) forming a water-insoluble protective film on the water-soluble protective film, the connection terminal parts, and the first face of the semiconductor substrate, subsequent to step (C).

14. The processing method of a semiconductor substrate according to claim 13, further comprising:
dicing the semiconductor substrate, subsequent to step (D).

15. The processing method of a semiconductor substrate according to claim 14, further comprising:
after the semiconductor substrate is diced, attaching a peeling film onto the water-insoluble protective film, and then removing the peeling film and the water-insoluble protective film from the water-soluble protective film.

16. The processing method of a semiconductor substrate according to claim 13, further comprising:
dicing the semiconductor substrate between step (B) and step (C).

17. A processed semiconductor substrate product comprising:
(a) a semiconductor substrate having a first face on which a plurality of semiconductor devices, each of which includes a semiconductor device main body part and connection terminal parts, are formed in a state in which the semiconductor devices are separate from each other; and
(b) a protective film that is formed with a UV curable adhesive layer and that covers the first face of the semiconductor substrate,
wherein an adhesive layer is cured on portions of the protective film that come into contact with the semiconductor device main body parts, and
wherein an adhesive layer of the protective film attached to an outer peripheral portion of the semiconductor substrate, and a region of the semiconductor substrate positioned between the semiconductor devices is not cured.

18. The processed semiconductor substrate product according to claim 17, wherein the protective film and the semiconductor substrate are diced.

19. A processed semiconductor substrate product comprising:
(a) a semiconductor substrate having a first face on which a plurality of semiconductor devices, each of which includes a semiconductor device main body part and connection terminal parts, are formed in a state in which the semiconductor devices are separate from each other; and
(b) a water-soluble protective film that is formed on semiconductor device main body parts except for a region of the first face of the semiconductor substrate on which the semiconductor devices are not formed, and the connection terminal parts.

20. The processed semiconductor substrate product according to claim 19, wherein the water-soluble protective film and the semiconductor substrate are diced.

21. The processed semiconductor substrate product according to claim 19, wherein a water-insoluble protective film is formed on the water-soluble protective film, the connection terminal parts, and the first face of the semiconductor substrate.

22. The processed semiconductor substrate product according to claim 21, wherein the water-insoluble protective film, the water-soluble protective film, and the semiconductor substrate are diced.

23. The processed semiconductor substrate product according to claim 19, wherein a second face of the semiconductor substrate opposite to the first face is polished.
